(19) United States
(12) Patent Application Publication
(10) Pub. No.: US 2011/0115055 A1
(43) Pub. Date: May 19, 2011

(54) SEMICONDUCTOR DEVICE AND MANUFACTURING METHOD THEREOF

(75) Inventors: Ryo NIIDE, Kanagawa (JP); Toshiya Nozawa, Kanagawa (JP)

(73) Assignee: RENESAS ELECTRONICS CORPORATION

(21) Appl. No.: 12/948,793

(22) Filed: Nov. 18, 2010

(30) Foreign Application Priority Data
Nov. 18, 2009 (JP) 2009-262797

(51) Int. Cl. H01L 29/866; H01L 21/20

(52) U.S. Cl. 257/603; 438/380; 257/E33.001; 257/E29.335; 257/E21.09

(57) ABSTRACT

To provide a technique that can decrease the leak current due to the photoelectric effect in a semiconductor device with a Zener diode. In a bidirectional Zener diode IZD having a trench structure in the invention, an upper electrode UE extends from an inside of an opening OP to cover a trench TR (isolation region). As shown in FIG. 8, in the bidirectional Zener diode IZD of the invention, the upper electrode UE is formed to cover the inner walls of the trenches TRs. Thus, even when light is applied to the bidirectional Zener diode IZD, the light can be prevented from entering the p-n junction formed at the boundary between the n-type semiconductor region NR and the p-type semiconductor region PR from the inner wall of the trench TR.

### CROSS-REFERENCE TO RELATED APPLICATIONS

The disclosure of Japanese Patent Application No. 2009-262797 filed on Nov. 18, 2009 including the specification, drawings and abstract is incorporated herein by reference in its entirety.

### BACKGROUND OF THE INVENTION

The present invention relates to semiconductor devices, a module and manufacturing methods thereof, and more particularly, to a technique effectively applied to a semiconductor device with a Zener diode and a manufacturing method thereof.

Japanese Unexamined Patent Publication No. Hei 06 (1994)-252384 (Patent Document 1) discloses a structure which includes a first conductive thin film for electrically coupling an anode pseudopotential intake region of a thyristor to a cathode region of a protective diode, and a second conductive thin film separately provided from the first thin film to cover the cathode region of the protective diode and a periphery of the cathode region.

### RELATED ART DOCUMENTS

### Patent Documents

### [Patent Document 1]

Japanese Unexamined Patent Publication No. 06 (1994)-252384

### SUMMARY OF THE INVENTION

Light emitting diodes (hereinafter referred to as a LED) have been widely used for various types of luminaires, such as a fluorescent light or a back light of a liquid crystal display, because of lower power consumption and longer life time. The LED is a semiconductor element whose market is expected to grow in the future.

A method for obtaining white light from the LED involves irradiating a garnet phosphor (YAG phosphor) with blue light emitted from a blue LED to thereby obtain the white light. Some blue LEDs have a low surge resistance, and hence are required to ensure the adequate surge resistance in order to be used for applications with high reliability.

Measures for ensuring the surge resistance involves, by way of example, coupling a Zener diode in anti-parallel to the LED. When coupling the Zener diode in anti-parallel to the LED, for example, a surge voltage applied to the LED by static electricity from the outside is also applied to the Zener diode coupled in anti-parallel to the LED. The Zener diode exhibits a breakdown and permits current in the reverse direction when the applied surge voltage exceeds the breakdown voltage. At this time, the voltage applied to the Zener diode exhibiting the breakdown keeps a Zener voltage. The Zener voltage is smaller than the surge voltage. That is, when the surge voltage is applied to the LED, the Zener diode coupled in anti-parallel to the LED is also subjected to the surge voltage, so that the breakdown of the Zener diode occurs. The voltage applied to the broken-down Zener diode becomes the constant Zener voltage. That is, upon the breakdown of the Zener diode, the surge voltage is absorbed by the Zener diode, and then converted into the Zener voltage. Thus, the LED coupled in anti-parallel to the Zener diode is subjected to the Zener voltage lower than the surge voltage. That is, the use of the Zener diode which is designed to make the Zener voltage lower than the breakdown voltage of the LED can protect the LED from the surge voltage. For the above reason, the Zener diode is used to protect the LED from the surge voltage.

The Zener diode with such a function is packaged separately from the LED, and is used as an external device for the LED. The LEDs, however, are required to be downsized. For this reason, mounting of the external Zener diode and the LED in the same package has been under consideration. Mounting a semiconductor chip with the LED and another semiconductor chip with the Zener diode in the same package poses the following new problems. Specifically, resin used in the package of the LED is transparent, and the LED itself emits light, so that the semiconductor chip with the Zener diode formed is consequently irradiated with the light. Thus, the p-n junction in the Zener diode is also irradiated with the light. In this case, electrons and holes generated by a photoelectric effect are moved by an electric field existing in the p-n junction, resulting in an increase in leak current. The increase in leak current from the Zener diode leads to a decrease in current which is to flow through the LED, which causes an increase in loss of the current. That is, when the leak current at the Zener diode is increased, more current is required to cause the LED to emit light, which wastes much current not contributing to the emission of light from the LED. This disadvantageously raises the problem of the increase in current loss.

Accordingly, it is an object of the present invention to provide a technique that can decrease the leak current due to the photoelectric effect in a semiconductor device with a Zener diode.

The above and other objects and the novel features of the invention will become apparent from the description of the present specification and the accompanying drawings.

The outline of representative aspects of the invention disclosed in the present application will be briefly described below.

A semiconductor device according to a representative embodiment of the invention includes a bidirectional Zener diode formed in a first semiconductor chip. At this time, the bidirectional Zener diode includes (a) a semiconductor substrate of a first conductive type, (b) a first semiconductor region of a second conductive type opposite to the first conductive type which is formed over the semiconductor substrate, and (c) a second semiconductor region of the first conductive type which is formed over the first semiconductor region. The Zener diode also includes (d) an isolation region formed in a predetermined depth from a surface of the second semiconductor region, and (e) a protective insulating film which is formed over the surface of the second semiconductor region so as to cover the second semiconductor region and the isolation region, and which has an opening formed for exposing a part of the second semiconductor region. The Zener diode further includes (f) a light blocking film formed over the protective insulating film including the opening, and (g) a back electrode formed at a back side of the semiconductor substrate. The light blocking film extends from an inside of the opening to cover the isolation region.

A manufacturing method of a semiconductor device according to another representative embodiment of the invention includes the steps of (a) preparing a semiconductor substrate of a first conductive type, and (b) forming a first semiconductor region of a second conductive type opposite to the first conductive type over the semiconductor substrate. The manufacturing method also includes the steps of (c) then forming a second semiconductor region of the first conductive type in an area from an inside to a surface of the first semiconductor region, and (d) forming an isolation region reaching in a predetermined depth from the surface of the second semiconductor region to isolate an active region. The manufacturing method further includes the steps of (e) subsequently forming a protective insulating film over the second semiconductor region and the isolation region, and (f) forming an opening in the protective insulating film formed in the active region by processing the protective insulating film to expose the second semiconductor region from the opening. The manufacturing method additionally includes the steps of (g) forming a light blocking film over an area from the second semiconductor region exposed from the opening to the protective insulating film, and (h) processing the light blocking film. At this time, in the step (h), the light blocking film is processed so as to extend from an inside of the opening to cover the isolation region.

The effects obtained by the representative aspects of the invention disclosed in the present application will be briefly described below.

Therefore, a semiconductor device with a Zener diode is provided which can reduce the leak current due to the photoelectric effect.

### BRIEF DESCRIPTION OF THE DRAWINGS

FIG. 1 is a circuit diagram showing a light emitting diode, and a Zener diode coupled in anti-parallel to the light emitting diode;

FIG. 2 is a circuit diagram showing a plurality of light emitting diodes coupled together in the form of a matrix;

FIG. 3 is a circuit diagram showing the light emitting diode, and a bidirectional Zener diode coupled in anti-parallel to the light emitting diode;

FIG. 4 is a circuit diagram showing a plurality of light emitting diodes coupled together in the form of a matrix;

FIG. 5 is a cross-sectional view showing one example of a device structure of the bidirectional Zener diode;

FIG. 6 is a cross-sectional view showing the device structure of a bidirectional Zener diode having a trench structure;

FIG. 7 is a plan view of the bidirectional Zener diode according to the first embodiment of the invention as viewed from the upper surface thereof;

FIG. 8 is a cross-sectional view taken along the line A-A in FIG. 7;

FIG. 9 is a graph showing current-voltage characteristics of the bidirectional Zener diode in the first embodiment;

FIG. 10 is a cross-sectional view showing the structure of a bidirectional Zener diode in a modified example;

FIG. 11 is a cross-sectional view showing a manufacturing step of the bidirectional Zener diode according to the first embodiment;

FIG. 12 is a cross-sectional view showing a manufacturing step of the bidirectional Zener diode following the step shown in FIG. 11;

FIG. 13 is a cross-sectional view showing a manufacturing step of the bidirectional Zener diode following the step shown in FIG. 12;

FIG. 14 is a cross-sectional view showing a manufacturing step of the bidirectional Zener diode following the step shown in FIG. 13;

FIG. 15 is a cross-sectional view showing a manufacturing step of the bidirectional Zener diode following the step shown in FIG. 14;

FIG. 16 is a cross-sectional view showing a manufacturing step of the bidirectional Zener diode following the step shown in FIG. 15;

FIG. 17 is a cross-sectional view showing a manufacturing step of the bidirectional Zener diode following the step shown in FIG. 16;

FIG. 18 is a cross-sectional view showing a manufacturing step of the bidirectional Zener diode following the step shown in FIG. 17;

FIG. 19 is a cross-sectional view showing a manufacturing step of the bidirectional Zener diode following the step shown in FIG. 18;

FIG. 20 is a cross-sectional view showing the structure of a bidirectional Zener diode according to a second embodiment;

FIG. 21 is a cross-sectional view showing the structure of a bidirectional Zener diode according to a third embodiment;

FIG. 22 is a plan view of a Zener diode according to a forth embodiment as viewed from the upper surface;

FIG. 23 is a cross-sectional view taken along the line A-A of FIG. 22;

FIG. 24 is a cross-sectional view showing the structure of a Zener diode in a modified example;

FIG. 25 is a cross-sectional view showing a manufacturing step of the bidirectional Zener diode according to the fourth embodiment;

FIG. 26 is a cross-sectional view showing a manufacturing step of the Zener diode following the step shown in FIG. 25;

FIG. 27 is a cross-sectional view showing a manufacturing step of the Zener diode following the step shown in FIG. 26;

FIG. 28 is a cross-sectional view showing a manufacturing step of the Zener diode following the step shown in FIG. 27;

FIG. 29 is a cross-sectional view showing a manufacturing step of the Zener diode following the step shown in FIG. 28;

FIG. 30 is a cross-sectional view showing a manufacturing step of the Zener diode following the step shown in FIG. 29;

FIG. 31 is a cross-sectional view showing a manufacturing step of the Zener diode following the step shown in FIG. 30;

FIG. 32 is a cross-sectional view showing a manufacturing step of the Zener diode following the step shown in FIG. 31;

FIG. 33 is a cross-sectional view showing the structure of a Zener diode according to a fifth embodiment;

FIG. 34 is a cross-sectional view showing the structure of a Zener diode according to a sixth embodiment;

FIG. 35 is a cross-sectional view showing a semiconductor device according to a seventh embodiment;

FIG. 36 is a cross-sectional view showing one section of the semiconductor device shown in FIG. 35;

FIG. 37 is a plan view showing another semiconductor device according to the seventh embodiment;

FIG. 38 is a cross-sectional view showing one section of the semiconductor device shown in FIG. 37;

FIG. 39 is a perspective view showing the structure of a composite package in the seventh embodiment;

FIG. 40 is a plan view of a bidirectional Zener diode according to an eighth embodiment as viewed from the upper surface;

FIG. 41 is a cross-sectional view taken along the line A-A of FIG. 40;

FIG. 42 is a cross-sectional view showing the structure of a bidirectional Zener diode in another modified example;

FIG. 43 is a cross-sectional view showing the structure of a bidirectional Zener diode in a further modified example;

FIG. 44 is a cross-sectional view showing a manufacturing step of a bidirectional Zener diode according to an eighth embodiment;

FIG. 45 is a cross-sectional view showing a manufacturing step of the bidirectional Zener diode following the step shown in FIG. 44;

FIG. 46 is a cross-sectional view showing a manufacturing step of the bidirectional Zener diode following the step shown in FIG. 45;

FIG. 47 is a cross-sectional view showing a manufacturing step of the bidirectional Zener diode following the step shown in FIG. 46;

FIG. 48 is a cross-sectional view showing a manufacturing step of the bidirectional Zener diode following the step shown in FIG. 47;

FIG. 49 is a cross-sectional view showing a manufacturing step of the bidirectional Zener diode following the step shown in FIG. 48;

FIG. 50 is a cross-sectional view showing a manufacturing step of the bidirectional Zener diode following the step shown in FIG. 49;

FIG. 51 is a plan view of a bidirectional Zener diode according to a ninth embodiment as viewed from the upper surface;

FIG. 52 is a cross-sectional view taken along the line A-A of FIG. 51;

FIG. 53 is a cross-sectional view showing the structure of a Zener diode in another modified example;

FIG. 54 is a cross-sectional view showing the structure of a Zener diode in a further modified example;

FIG. 55 is a plan view showing a semiconductor device according to a tenth embodiment; and

FIG. 56 is a cross-sectional view showing one section of the semiconductor device shown in FIG. 55.

### DETAILED DESCRIPTION OF THE PREFERRED EMBODIMENTS

The following preferred embodiments of the invention may be described below by being divided into a plurality of sections or embodiments for convenience, if necessary, which are not independent from each other except when specified otherwise. One of the sections or embodiments is a modified example, the details, a supplemental explanation, or the like of a part or all of the other.

When reference is made to the number of elements or the like (including the number of pieces, numerical values, quantity, range, etc.) in the following description of the embodiments, the number thereof is not limited to a specific number, and may be greater than, or less than, or equal to the specific number, unless otherwise specified and definitely limited to the specific number in principle.

It is also needless to say that components (including elements or process steps, etc.) employed in the following description of the embodiments are not always essential, unless otherwise specified and considered to be definitely essential in principle.

Similarly, in the following description of the shapes, positional relations and the like of the components or the like in the embodiments, they will include those substantially analogous or similar to their shapes or the like, unless otherwise specified and considered not to be definitely so in principle, etc. This is also similarly applied even to the above-described numerical values and range.

Members having the same functions are designated by the same reference numerals through all drawings for explaining the embodiments of the invention in principle, and thus the repeated description thereof will be omitted. For easy understanding, hatched areas are given even to plan views.

### First Embodiment

A light-emitting diode is a semiconductor device that emits light by causing a direct current to flow therethrough. The principle of light emission of the light-emitting diode is as follows. Specifically, when a p-n junction provided in the light-emitting diode is forward biased, holes are implanted from a p-type semiconductor region and electrons are implanted from an n-type semiconductor region into the p-n junction. The electrons recombine with the holes at the p-n junction. In the recombination, the electrons in a conduction band of a band structure meet the holes in a valance band, while releasing energy corresponding to the band gap. That is, in the recombination, the energy corresponding to the band gap is released. The release of the energy corresponding to the band gap is performed by emitting light with the energy corresponding to the band gap. The semiconductor device using this phenomenon is a light-emitting diode. The light-emitting diode can change the band gap by selecting material. The light-emitting diode emits light equivalent to the energy corresponding to the band gap. Thus, the change of the band gap leads to a change in energy of the emitted light. The energy of light is proportional to the frequency of light (E=hν). The change in energy of the emitted light means the change in frequency of the emitted light. That is, in the light-emitting diode, light with different frequencies can be emitted by changing the band gap. In other words, the production of light-emitting diodes with different band gaps can provide the light-emitting diodes emitting lights in different colors. Specifically, the light-emitting diodes emitting red, green, and blue lights are produced.

Such light-emitting diodes have been widely used for various types of luminaires, such as a fluorescent light or a back light of a liquid crystal display, because of lower power consumption and longer life time. Some LEDs have a low surge resistance, and hence are required to ensure the adequate surge resistance in order to be used for applications with high reliability.

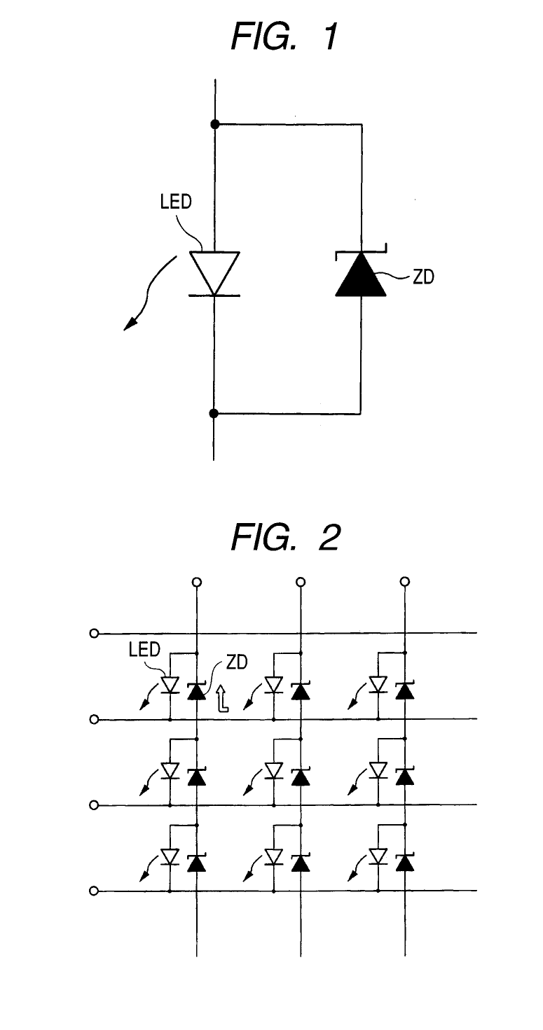

Measures for ensuring the surge resistance involves, by way of example, coupling a Zener diode in anti-parallel to the light-emitting diode. FIG. 1 is a circuit diagram showing a light-emitting diode LED and a Zener diode ZD coupled in anti-parallel to the light-emitting diode LED. As shown in FIG. 1, the light-emitting diode LED is coupled to the Zener diode ZD so as to protect the light-emitting diode LED from the surge voltage. For example, when a surge voltage is applied to the light-emitting diode LED by static electricity or the like from the outside in coupling the Zener diode ZD in anti-parallel to the light-emitting diode LED in this way, the Zener diode ZD which is coupled in anti-parallel to the diode LED is also subjected to the surge voltage. When the surge voltage applied exceeds the breakdown voltage, the breakdown of the Zener diode ZD occurs to permit current in the reverse direction. At this time, the voltage applied to the broken-down Zener diode ZD is kept at a Zener voltage. The Zener voltage is smaller than the surge voltage. In other words, when the surge voltage is applied to the light-emitting diode LED, the surge voltage is also applied to the Zener diode ZD coupled in anti-parallel to the light-emitting diode LED, which causes the breakdown of the Zener diode ZD. The voltage applied to the broken-down Zener diode ZD becomes a constant Zener voltage. That is, the breakdown of the Zener diode ZD causes the surge voltage to be absorbed by the Zener diode ZD, so that the surge voltage is converted into the Zener voltage. Thus, the Zener voltage which is lower than the surge voltage is applied to the light-emitting diode LED coupled in anti-parallel to the Zener diode ZD. Accordingly, the use of the Zener diode ZD which makes the Zener voltage smaller than the breakdown voltage of the light-emitting diode LED can protect the light-emitting diode LED from the surge voltage.

The above single light-emitting diode LED is sometimes used, but a plurality of light-emitting diodes LEDs are combined together in use so as to further increase the light intensity. FIG. 2 is a circuit diagram showing the structure of the light-emitting diodes LEDs coupled together in the form of a matrix. As shown in FIG. 2, the light-emitting diodes LEDs are arranged in an array. Each of the light-emitting diodes LEDs is coupled in anti-parallel to the Zener diode ZD for protecting the light-emitting diode LED from the surge voltage. At this time, for example, the current often flows in the direction indicated by the thick arrow in FIG. 2, depending on, for example, conditions of voltage applied to the light-emitting diodes LEDs disposed in the array. That is, current often flows through the Zener diode ZD in the forward direction of the Zener diode coupled in anti-parallel to the light-emitting diode LED. This current is called “sneak current”, which is a phenomenon caused in using the light-emitting diodes LEDs coupled in the form of a matrix. The sneak current may disadvantageously cause the undesired light-emitting diode LED to emit light. The occurrence of the sneak current increases useless current not contributing to the emission of light from the light-emitting diode LED, which interrupts reduction in power consumption. That is, the Zener diode ZD is used to protect the light-emitting diode LED from the surge voltage. When the light-emitting diodes LEDs are arranged in the form of the matrix, the sneak current flowing in the forward direction of the Zener diode ZD becomes problematic.

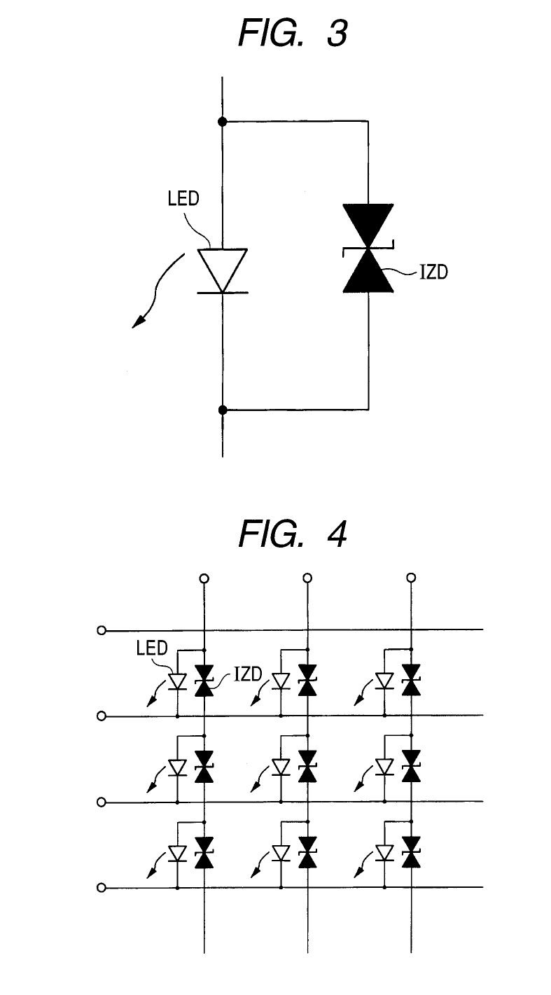

For this reason, the bidirectional Zener diode IZD and not the normal Zener diode ZD is used as a device coupled in anti-parallel to the light emitting diode LED. FIG. 3 is a circuit diagram showing the light-emitting diode LED and the bidirectional Zener diode IZD coupled in anti-parallel to the light-emitting diode LED. The bidirectional Zener diode IZD shown in FIG. 3 is a device that does not allow current to flow in both the forward direction and the reverse direction. The use of the bidirectional Zener diode IZD has the following advantages.

FIG. 4 is a circuit diagram showing the structure of the light-emitting diodes LEDs coupled together in the form of a matrix. As shown in FIG. 4, the light-emitting diodes LEDs are arranged in the array, and each light-emitting diode LED is coupled in parallel to the bidirectional Zener diode IZD for protecting the light-emitting diode LED from the surge voltage. At this time, for example, the use of the Zener diode ZD shown in FIG. 2 causes sneak current, depending on, for example, the conditions of voltage applied to the light-emitting diodes LEDs arranged in the array. In contrast, the use of the bidirectional Zener diode IZD shown in FIG. 4 does not allow the current to flow in both the forward direction and the reverse direction even when a condition for generating the above sneak current is satisfied, and hence can suppress the occurrence of the sneak current. That is, the coupling of the bidirectional Zener diodes IZDs in parallel to the light-emitting diodes LEDs can suppress the occurrence of the sneak current even when the light-emitting diodes LEDs are arranged in the form of a matrix. As a result, this structure can prevent the emission of light from the undesired light-emitting diode LED, or the generation of useless current flow not contributing to the light emission from the light-emitting diode LED due to the sneak current.

Further, the use of the bidirectional Zener diode IZD has the advantage that the light-emitting diode LED can be protected from serge voltages with different polarities. In either case where the surge voltage with a different polarity is applied to the bidirectional Zener diode IZD, the surge voltage is applied in the reverse direction with respect to the corresponding bidirectional Zener diode IZD. In each case, the breakdown of the bidirectional Zener diode IZD occurs, so that the surge voltage is absorbed and converted into the Zener voltage. Thus, even when the surge voltages with different polarities are applied to the light-emitting diodes LED, the light-emitting diode LED can be protected from the surge voltage.

In particular, only one bidirectional Zener diode LZD can protect the light-emitting diode LED from the surge voltage with different polarities. In contrast, in the case of using the normal Zener diode, two Zener diodes coupled in the reverse direction are required to protect the light-emitting diodes LEDs from the serge voltages with different polarities. This means an increase in mounting area of the Zener diodes. In order to protect the light-emitting diodes LEDs from the surge voltages with different polarities, two normal Zener diodes are needed as the device. However, the use of the only one bidirectional Zener diode IZD as the device can also achieve the effect. As a result, the use of the bidirectional Zener diode IZD can reduce the mounting area about by half as compared to the use of the two Zener diodes.

The first embodiment of the invention is a technical idea based on the premise of using the bidirectional Zener diode IZD with the above advantages. There are various device structures that achieve the bidirectional Zener diode IZD. The first embodiment relates to the so-called trench bidirectional Zener diode IZD. Now, the first embodiment will describe the reason for selecting the trench bidirectional Zener diode IZD in use from among the device structures achieving the bidirectional Zener diode IZD. A module structure (a package structure, a semiconductor device) related to FIGS. 2, 4 including the light-emitting diodes LEDs and the bidirectional Zener diodes IZD is described later in a seventh embodiment through a tenth embodiment. This module structure is included in a LED display device included in such as a TV or a mobile device, for example.

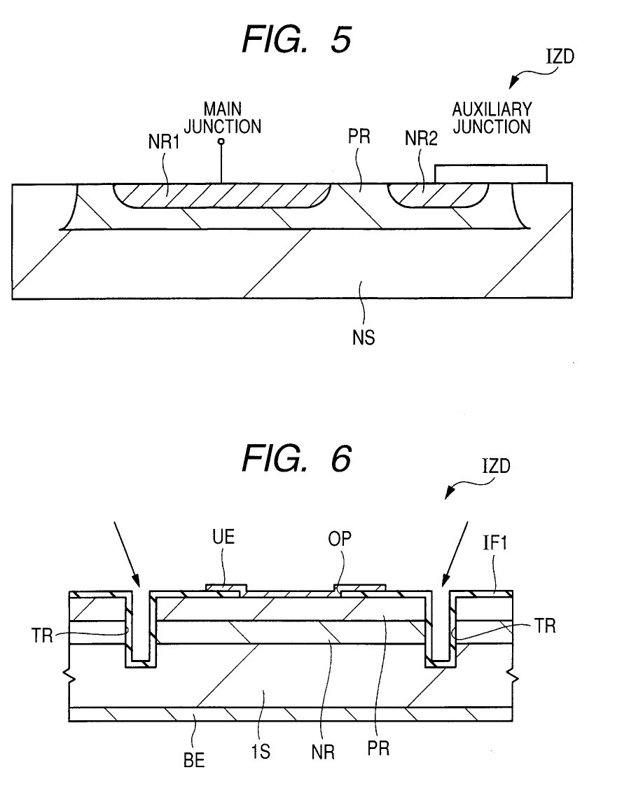

FIG. 5 is a cross-sectional view showing an example of a device structure of a bidirectional Zener diode IZD. Referring to FIG. 5, the bidirectional Zener diode IZD includes an n-type semiconductor substrate NS, and a p-type semiconductor region PR formed in the n-type semiconductor substrate NS. The diode IZD further includes an n-type semiconductor region NR1 and an n-type semiconductor region NR2 formed in the p-type semiconductor region PR. Thus, an NPN junction can be formed for realizing the bidirectional Zener diode IZD.

In the bidirectional Zener diode IZD shown in FIG. 5, for example, the n-type semiconductor region NR1 and the n-type semiconductor region NR2 are formed by introducing n-type impurities, such as phosphorus (P), into the p-type semiconductor region PR by ion implantation, and then diffusing the n-type impurities by heat treatment. At this time, the n-type semiconductor region NR1 and the n-type semiconductor region NR2 are selectively formed over a part of the semiconductor substrate NS, but not over the entire surface of the semiconductor substrate NS, so that junction ends are generated at the n-type semiconductor region NR1 and the n-type semiconductor region NR2. The semiconductor region has a curvature radius decreased at its junction end. Especially, an electric field concentration occurs at the steep junction end with the small curvature radius. That is, in the bidirectional Zener diode IZD shown in FIG. 5, the junction end with the small curvature radius is formed, and the electric field concentration occurs at the junction end. The occurrence of electric field concentration at the junction end reduces the surge resistance.

For example, suppose that the surge voltage is applied to the bidirectional Zener diode IZD shown in FIG. 5. In this case, the electric field concentration occurs at the junction end with the small curvature radius. The junction end with the small curvature radius is subjected to a larger electric field than the other junction regions. Specifically, in the bidirectional Zener diode IZD shown in FIG. 5, even when the surge voltage is applied to the other flat junction regions at such a level that does not cause the breakdown, the electric field concentration may occur at the junction end with the small curvature radius to induce the breakdown of the diode. As a result, the breakdown current concentrically flows through only the junction end with the small curvature radius to generate heat, which may break the p-n junction at the junction end. Thus, the bidirectional Zener diode IZD shown in FIG. 5 has the problem of reduction in surge resistance.

The p-n junction is formed at a boundary between the n-type semiconductor region NR1 and the p-type semiconductor region PR in the bidirectional Zener diode IZD shown in FIG. 5. The p-n junction is formed not only at the flat horizontal plane, but also at the junction ends formed at both ends of the n-type semiconductor region NR1. As a result, when a reverse bias voltage is applied to the p-n junction, a depletion layer extends from the horizontal plane of the p-n junction in the vertical direction (in the thickness direction of the semiconductor substrate NS), and also extends from the p-n junction of the junction end in the lateral direction (in the horizontal direction). In this way, when the reverse bias voltage is applied to the p-n junction in the bidirectional Zener diode IZD shown in FIG. 5, the depletion layer extends not only in the vertical direction, but also in the lateral direction, which results in variations in Zener voltage in both directions.

The bidirectional Zener diode IZD shown in FIG. 5 has a main junction and an auxiliary junction formed therein so as to suppress variations in Zener voltage. That is, the bidirectional Zener diode IZD shown in FIG. 5 has the main junction between the n-type semiconductor region NR1 and the p-type semiconductor region PR, and the auxiliary junction between the n-type semiconductor region NR2 and the p-type semiconductor region PR. Thus, a formed current route can be, for example, from the n-type semiconductor region NR1 of the main junction, to the p-type semiconductor region PR, the n-type semiconductor region NR2 of the auxiliary junction, and then the semiconductor substrate NS in the lateral direction. As a result, variations in Zener voltage in both directions can be suppressed.

In the bidirectional Zener diode IZD shown in FIG. 5, the main junction and the auxiliary junction are formed so as to suppress the variations in Zener voltage. Thus, not only the main junction, but also the auxiliary junction needs to be formed in the semiconductor chip, which may disadvantageously result in an increase in size of the semiconductor chip.

As can be seen from the above description, the bidirectional Zener diode IZD shown in FIG. 5 has the problems of reduction in serge resistance, and increase in size of the semiconductor chip.

Next, the device structure of the trench bidirectional Zener diode IZD will be described below. FIG. 6 is a cross-sectional view showing the device structure of the trench bidirectional Zener diode IZD. As shown in FIG. 6, a back electrode BE is comprised of, for example, a gold film over a back surface (lower surface) of the p-type semiconductor substrate 1S. In contrast, the n-type semiconductor region NR is formed over the upper surface of the p-type semiconductor substrate 1S. A p-type semiconductor region PR is formed over the n-type semiconductor region NR. Thus, the PNP junction is formed by the semiconductor substrate 1S, the n-type semiconductor region NR, and the p-type semiconductor region PR.

A pair of trenches TR is formed to reach the inside of the semiconductor substrate 1a from the surface of the p-type semiconductor region PR through the p-type semiconductor region PR and the n-type semiconductor region NR. A region interposed between the pair of trenches TRs is an active region serving as the bidirectional Zener diode IZD. In other words, in the trench bidirectional Zener diode IZD, the active region is isolated by the pair of trenches TRs, and the isolated active region has the bidirectional Zener diode IZD formed therein.

A protective insulating film IF1 is formed over the surface of the p-type semiconductor region PR with the trenches TRs formed therein. Specifically, the protective insulating film IF1 is formed over the surface of the p-type semiconductor region PR including the inner surfaces of the trenches TRs. The protective insulating film IF1 is comprised of, for example, a silicon oxide film, a silicon nitride film, a phospho silicate glass (PSG) film which is a glassy film provided by adding phosphorus into a silicon oxide film, or the like.

An opening OP is formed in the protective insulating film IF1, and an upper electrode UE is formed over the protective insulating film IF1 including the opening OP. Specifically, the opening OP is formed in the active region interposed between a pair of trenches TRs, and the p-type semiconductor region PR is exposed at the bottom of the opening OP. The upper electrode UE is formed over the protective insulating film IF1 in the active region from the inside of the opening OP. In this way, the upper electrode UE is in contact with the p-type semiconductor region PR exposed at the bottom of the opening OP. The upper electrode UE is comprised of a conductive film, such as a metal film or a metal compound film, for example, an aluminum-silicon film.

The trench bidirectional Zener diode IZD with this arrangement has the following advantages. In the trench bidirectional Zener diode IZD, the n-type semiconductor region NR is formed over the entire upper surface of the semiconductor substrate 1S, and the p-type semiconductor region PR is formed over the entire upper surface of the n-type semiconductor region NR. In the trench bidirectional Zener diode IZD, both the boundary between the semiconductor substrate 1S and the n-type semiconductor region NR, and the boundary between the n-type semiconductor region NR and the p-type semiconductor region PR are flat horizontal ones. This means that a region with a small curvature radius is not formed in the boundary between the semiconductor substrate 1S and the n-type semiconductor region NR, and in the boundary between the n-type semiconductor region NR and the p-type semiconductor region PR. That is, in the trench bidirectional Zener diode IZD, the steep junction end with the small curvature radius is not formed, unlike the bidirectional Zener diode IZD shown in FIG. 5. As a result, the local electric field concentration does not occur in the trench bidirectional Zener diode IZD. From this point, the trench bidirectional Zener diode IZD has the advantage of improving the surge resistance.

The respective p-n junctions are formed at the horizontal boundary between the semiconductor substrate 1S and the n-type semiconductor region NR, and at the horizontal boundary between the n-type semiconductor region NR and the p-type semiconductor region PR in the trench bidirectional Zener diode IZD. Thus, when the reverse bias voltage is applied to each of the p-n junctions, the depletion layer extends only in the vertical direction from each p-n junction. That is, the depletion layer does not extend from the p-n junction of the junction end in the lateral direction (horizontal direction) in the trench bidirectional Zener diode IZD shown in FIG. 6, unlike the bidirectional Zener diode IZD shown in FIG. 5. Thus, the trench bidirectional Zener diode IZD can suppress the variations in Zener voltage in both directions as compared to the bidirectional Zener diode IZD shown in FIG. 5. That is, the trench bidirectional Zener diode IZD can suppress the variations in Zener voltage because of the structure. In order to suppress the variations in Zener voltage, it is not necessary to form the main junction and the auxiliary junction. Thus, the trench bidirectional Zener diode IZD has the advantage of reduction in size of the semiconductor chip as compared to the bidirectional Zener diode IZD shown in FIG. 5. As mentioned above, the trench bidirectional Zener diode IZD shown in FIG. 6 has the advantages of improving the surge resistance and of reducing the size of the semiconductor chip as compared to the bidirectional Zener diode IZD shown in FIG. 5. For this reason, the first embodiment selects and employs the trench bidirectional Zener diode IZD from among the device structures realizing the bidirectional Zener diodes IZDs.

The trench bidirectional Zener diode IZD with such a function is normally packaged separately from the light-emitting diode LED and used as an exterior device for the light-emitting diode LED. The LEDs, however, are required to be downsized. For this reason, the external bidirectional Zener diode IZD and the light-emitting diode LED are considered to be mounted in the same package. Mounting the semiconductor chip with the light-emitting diode LED and another semiconductor chip with the bidirectional Zener diode IZD in the same package raises the following new problems. In other words, when mounting the semiconductor chip with the trench bidirectional Zener diode IZD and the semiconductor chip with the light-emitting diode LED in the same package, the following problems are raised. The problems will be described below.

The resin used in the package of the light-emitting LED is transparent, and the light-emitting diode LED itself emits light, so that the semiconductor chip with the trench bidirectional Zener diode IZD is consequently irradiated with the light. At this time, as shown in FIG. 6, the light is applied to the inner walls of the trenches TRs, and then applied to the p-n junction formed between the n-type semiconductor region NR and the p-type semiconductor region PR through the inner walls of the trenches TRs. When the light is applied to the p-n junction, the photoelectric effect is generated. Specifically, when the light with the energy above the band gap enters the p-n junction or the p-type semiconductor region PR, or the n-type semiconductor region NR included in the p-n junction, electrons which are valence electrons of silicon absorb the energy of the incident light to be excited into a conduction band of silicon. Thus, electrons move into the conduction band of silicon, while generating holes in the valence band of Si. The electrons excited in the conduction band of silicon are accelerated by an electric field in the p-n junction to thereby move from the p-type semiconductor region PR (conduction band) toward the n-type semiconductor region NR (conduction band). In contrast, the holes generated in the valence band of silicon are accelerated by the electric field in the p-n junction to thereby move from the n-type semiconductor region NR (valence band) toward the p-type semiconductor region PR (valence band). Thus, the leak current flowing from the n-type semiconductor region NR to the p-type semiconductor region PR may be increased in the trench bidirectional Zener diode IZD. The increase in leak current in the bidirectional Zener diode IZD decreases the current to pass through the light-emitting diode LED coupled in anti-parallel to the bidirectional Zener diode IZD, which leads to much loss of current. That is, when leak current at the bidirectional Zener diode IZD is increased, more current is required to cause the light-emitting diode LED to emit light, which wastes much current not contributing to the emission of light from the light-emitting diode LED. This disadvantageously raises the problem of the increase in current loss.

Thus, the first embodiment is based on the premise of using the trench bidirectional Zener diode IZD which is mounted together with the light-emitting diode LED in one package. The trench bidirectional Zener diode IZD of the first embodiment has means for decreasing leak current due to the photoelectric effect. The following will describe the trench bidirectional Zener diode IZD that can reduce the leak current due to the photoelectric effect with reference to the accompanying drawings.

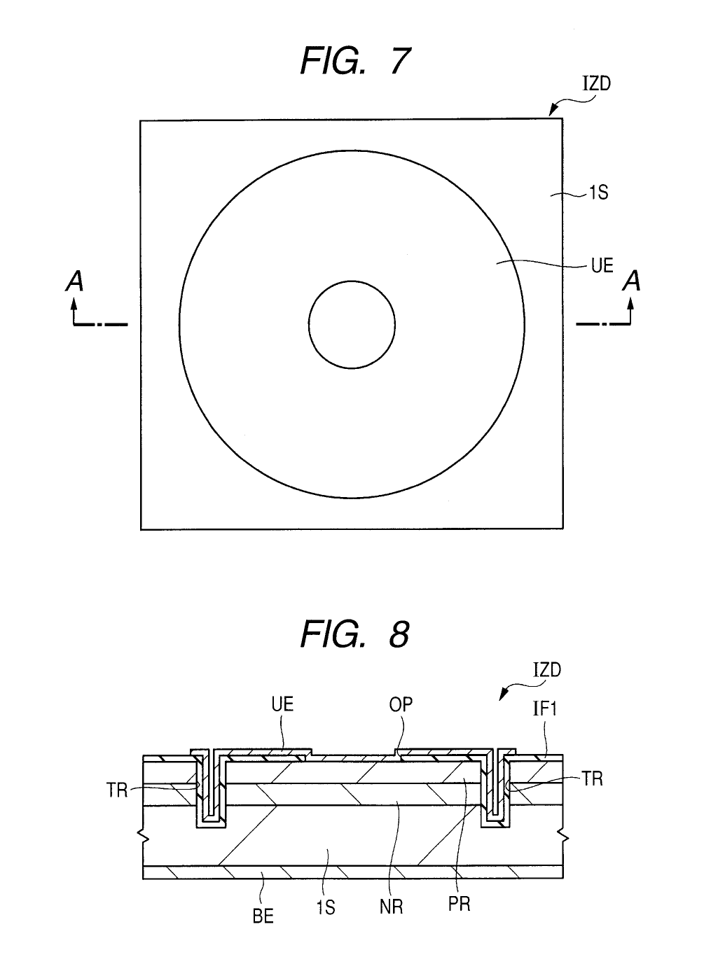

FIG. 7 is a plan view of the bidirectional Zener diode IZD of the first embodiment as viewed from the upper surface. In FIG. 7, a circular upper electrode UE is formed over a rectangular semiconductor substrate 1S. Then, the detailed structure of the bidirectional Zener diode IZD of the first embodiment will be described below with reference to FIG. 8.

FIG. 8 is a cross-sectional view taken along the line A-A of FIG. 7. As shown in FIG. 8, a back electrode BE made of, for example, a gold film is formed over the back surface (lower surface) of a p-type semiconductor substrate 1S. In contrast, an n-type semiconductor region NR is formed over the upper surface of the p-type semiconductor substrate 1S, and a p-type semiconductor region PR is formed over the n-type semiconductor region NR. The PNP junction of the bidirectional Zener diode IZD is formed by the semiconductor substrate 1S, the n-type semiconductor region NR, and the p-type semiconductor region PR.

A pair of trenches TR is formed to reach the inside of the semiconductor substrate 1S from the surface of the p-type semiconductor region PR through the p-type semiconductor region PR and the n-type semiconductor region NR. An area interposed between the pair of trenches TRs is an active region serving as the bidirectional Zener diode IZD. In other words, in the trench bidirectional Zener diode IZD, the active region is isolated by the pair of trenches TRs. The bidirectional Zener diode IZD is formed in the isolated active region.

In the bidirectional Zener diode IZD of the first embodiment, the trench TR has the following functions. For example, suppose that no trench TR is formed. Also in this case, the n-type semiconductor region NR is formed over the upper surface of the p-type semiconductor substrate 1S, and the p-type semiconductor region PR is formed over the n-type semiconductor region NR. The PNP junction is formed, and serves as the bidirectional Zener diode IZD. When the trench TR is not formed, however, the PNP junction reaches the end of the semiconductor substrate 1S. That is, in a case where no trench TR is formed, the active region serving as the bidirectional Zener diode IZD reaches the end of the semiconductor substrate 1S. In other words, the PNP junction for determining the electric characteristics of the bidirectional Zener diode IZD is formed up to the end of the semiconductor substrate 1S.

The end of the semiconductor substrate 1S is cut by dicing. Thus, if the PNP junction that determines the important properties of the bidirectional Zener diode IZD is formed up to the end of the semiconductor substrate 1S, the PNP junction may be damaged by the dicing. This may result in variations in characteristics of the bidirectional Zener diode IZD.

Contaminants tend to enter the end of the semiconductor substrate 1S from the outside. When the PNP junction that determines the important properties of the bidirectional Zener diode IZD is formed up to the end of the semiconductor substrate 1S, the PNP junction may be affected by the contaminants, which results in variations in characteristics of the bidirectional Zener diode IZD.

In contrast, when the trenches TRs are formed, the region interposed between the pair of trenches TRs becomes the active region for the bidirectional Zener diode IZD. That is, the trench TR can separate the active region of the bidirectional Zener diode IZD from the outside end region thereof. As a result, even when the end of the semiconductor substrate 1S is cut by dicing, the PNP junction of the bidirectional Zener diode IZD positioned inside the trench TR is protected without being damaged. Since contaminants invading the end of the semiconductor substrate 1S are interrupted by the trenches TRs, the PNP junction of the bidirectional Zener diode IZD which is formed inside the trench TR is protected from the pollutant. Accordingly, the formation of the trench TR can suppress variations in characteristics of the bidirectional Zener diode IZD. In other words, the trench TR serves as an isolation region for separating the active region of the bidirectional Zener diode IZD from the end region of the semiconductor substrate 1S.

The protective insulating film IF1 is formed over the surface of the p-type semiconductor region PR with such trenches TRs formed therein. Specifically, the protective insulating film IF1 is formed over the surface of the p-type semiconductor region PR including the inner walls of the trenches TRs. The protective insulating film IF1 is comprised of, for example, a silicon oxide film, a silicon nitride film, a phospho silicate glass (PSG) film which is a glassy film provided by adding phosphorus into a silicon oxide film, or the like.

The opening OP is formed in the protective insulating film IF1, and the upper electrode UE is formed over the protective insulating film IF1 including the opening OP. Specifically, the opening OP is formed in the active region interposed between a pair of trenches TRs, and the p-type semiconductor region PR is exposed at the bottom of the opening OP. In the first embodiment, the upper electrode UE is formed to extend from the inside of the opening OP over the protective insulating film IF1 covering the inner wall of the trench TR. Thus, the upper electrode UE is in contact with a part of the p-type semiconductor region PR exposed at the bottom of the opening OP. The upper electrode UE is comprised of a conductive film, such as a metal film or a metal compound film, for example, an aluminum-silicon film.

The first feature of the first embodiment is that the upper electrode UE extends from the inside of the opening OP to cover the trench TR (isolation region). That is, as shown in FIG. 8, in the bidirectional Zener diode IZD of the first embodiment, the upper electrode UE is formed so as to cover the inner walls of the trenches TRs. The upper electrode UE is comprised of a conductive film containing metal, for example, an aluminum-silicon film, and thus has a light blocking effect. In the bidirectional Zener diode IZD of the first embodiment, the inner walls of the trenches TR are covered with the upper electrode UE (light blocking film) having the light blocking effect. Even when the light is applied to the bidirectional Zener diode IZD, the light can be prevented from entering the p-n junction formed at the boundary between the n-type semiconductor region NR and the p-type semiconductor region PR from the inner wall of the trench TR. Thus, the occurrence of the photoelectric effect at the p-n junction can be prevented. That is, the bidirectional Zener diode IZD of the first embodiment can reduce the leak current flowing from the n-type semiconductor region NR to the p-type semiconductor region PR due to the photoelectric effect in the p-n junction. This means that the current passing through the light-emitting diode LED coupled in parallel to the bidirectional Zener diode IZD can be ensured to reduce the loss of current. Since the leak current at the bidirectional Zener diode IZD can be reduced, the Zener diode IZD can improve the efficiency of use of current for emission of light from the light-emitting diode LED to thereby reduce the useless current not contributing to the light emission of the light-emitting diode LED. As described above, the bidirectional Zener diode IZD of the first embodiment can reduce the leak current due to the photoelectric effect, and as a result, can improve the efficiency of use of current at the diode LED.

The formation of the upper electrode UE so as to cover the inner wall of the trench TR can also obtain the following advantages. For example, when the trenches TR are formed in the upper surface (front surface) side of the semiconductor substrate 1S, warpage tends to occur in the semiconductor substrate 1S due to a difference in stress between the surface of the semiconductor substrate 1S with the trench TR formed therein and the back surface of the substrate 1S without the trench TR. At this time, since the upper electrode UE is formed so as to cover the inner walls of the trenches TRs in the first embodiment, the upper electrode UE formed over the inner walls of the trenches TRs releases the warpage of the semiconductor substrate 1S. In other words, in the first embodiment, the upper electrode UE is formed to cover the inner walls of the trenches TRs for the purpose of preventing the light from entering the p-n junction formed at the boundary between the n-type semiconductor region NR and the p-type semiconductor region PR from the inner wall of the trench TR. This arrangement can also have a spillover effect for preventing the warpage of the semiconductor substrate 1S.

Next, the second feature of the first embodiment is that the upper electrode UE formed so as to cover the inner wall of the trench TR is not formed up to the end region of the semiconductor substrate 1S. For example, if the upper electrode UE is formed up to the end region of the semiconductor substrate 1S, the upper electrode UE may corrode in contact with moisture entering the end region of the semiconductor substrate 1S from the outside, which may result in variations in characteristics of the bidirectional Zener diode IZD. In contrast, the upper electrode UE in the bidirectional Zener diode IZD of the first embodiment does not extend up to the end region of the semiconductor substrate 1S, so that the moisture entering the end region of the substrate 1S from the outside can be prevented from being brought into contact with the upper electrode UE. Thus, the first embodiment can suppress the corrosion of the upper electrode UE, and thus can improve the reliability of the bidirectional Zener diode IZD.

The upper electrode UE not formed up to the end region of the semiconductor substrate 1S can obtain the following advantages. For example, when the upper electrode UE is formed up to the end region of the substrate 1S which is an outside region of the trench TR, the presence of defects of the formed protective insulating film IF1 brings the upper electrode UE into direct contact with the semiconductor region formed under the protective insulating film IF1. Then, the semiconductor region inside the trench TR (active region) may be coupled to the semiconductor region outside the trench TR, which may cause variations in characteristics of the diode. That is, the bidirectional Zener diode IZD does not possibly work. In contrast, in a case where the upper electrode UE does not extend to an outer end region of the trench TR like the first embodiment, the upper electrode UE can be prevented from being in direct contact with the semiconductor region in the end region even if the protective insulating film IF1 formed in the outer end region has defects. Thus, in the first embodiment, even when the protective insulating film IF1 has some defects in the outer end region of the trench TR, the contact between the upper electrode UE and the semiconductor region can be prevented, which can suppress variations in characteristics of the bidirectional Zener diode IZD to thereby improve the reliability of the bidirectional Zener diode IZD.

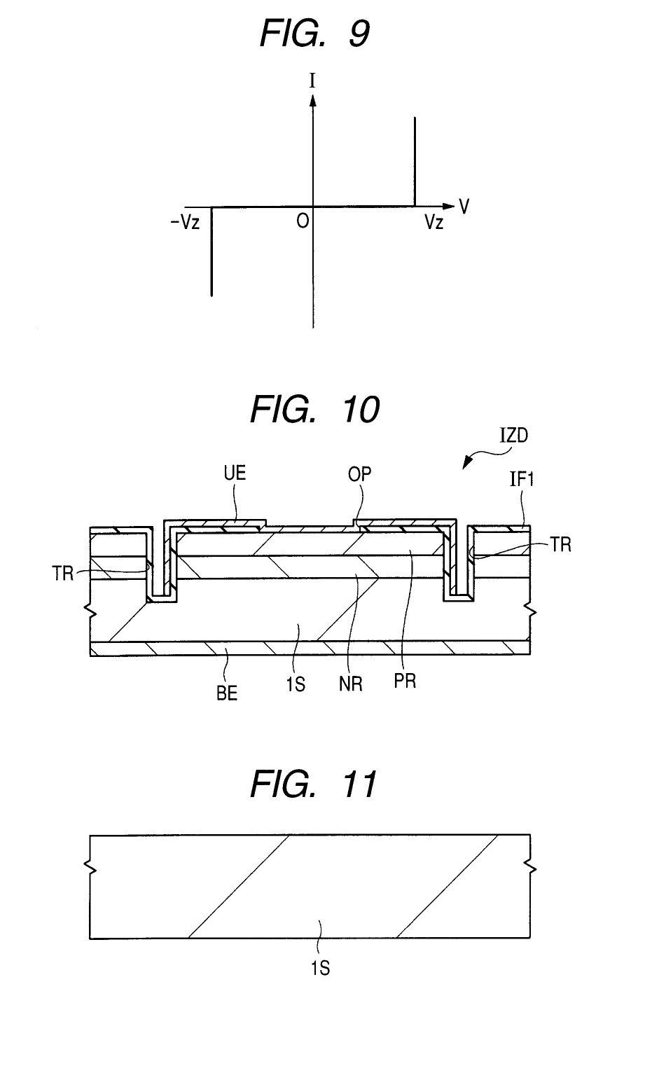

Further, the bidirectional Zener diode IZD of the first embodiment has the following advantage. FIG. 9 is a graph showing the current(I)-voltage(V) characteristic of the bidirectional Zener diode IZD of the first embodiment. In FIG. 9, the horizontal axis indicates the voltage (V), and the longitudinal axis indicates the current (I). As shown in FIG. 9, the bidirectional Zener diode IZD of the first embodiment has the trench structure, and as a result has the same characteristics in both forward and reverse directions. That is, in FIG. 9, the absolute value of the Zener voltages Vz in the forward direction is equal to that in the reverse direction. Therefore, the bidirectional Zener diode IZD of the first embodiment can be used regardless of polarity as shown in FIG. 9. For example, the user using the bidirectional Zener diode IZD does not need to confirm the polarities in the forward direction and reverse direction. The convenience of the diode is advantageously improved as mentioned above.

Now, a modified example of the bidirectional Zener diode IZD in the first embodiment will be described below. FIG. 10 is a cross-sectional view showing the structure of the bidirectional Zener diode IZD in the modified example. The bidirectional Zener diode IZD shown in FIG. 10 has substantially the same structure as that of the bidirectional Zener diode IZD shown in FIG. 8, and thus only different points between them will be described below. Specifically, in the bidirectional Zener diode IZD shown in FIG. 8, the upper electrode UE is formed so as to cover the inner walls (side surfaces on both sides) of each trench TR. In contrast, in the bidirectional Zener diode IZD shown in FIG. 10, the upper electrode UE is formed to extend from the inside of the opening OP, and to cover at least one side of both sides of the trench TR (side surface on one side) in contact with the active region with the bidirectional Zener diode IZD formed therein. Also, with this arrangement, light can be prevented from entering the p-n junction formed at the boundary between the n-type semiconductor region NR and the p-type semiconductor region PR from the inner wall of the trench TR. Thus, the occurrence of the photoelectric effect in the p-n junction can be suppressed. When the light is not applied to the p-n junction positioned in the active region formed on the inner side of both side surfaces of the trench TR, the leak current due to the photoelectric effect can be reduced. From this point, in the bidirectional Zener diode IZD of the first embodiment, like the diode IZD shown in FIG. 10, the upper electrode UE may be formed so as to cover at least one side of both sides of the trench TR (side surface on one side) in contact with the active region with the bidirectional Zener diode IZD formed therein.

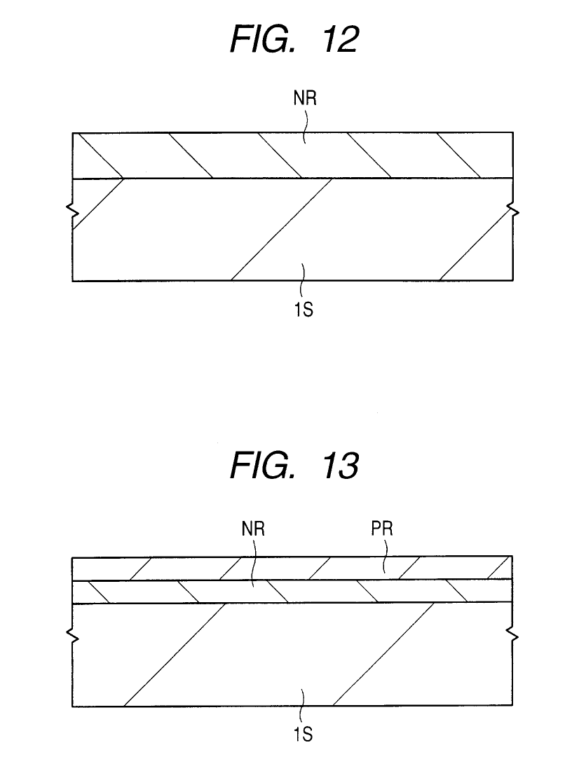

The bidirectional Zener diode IZD of the first embodiment is structured as mentioned above, and a manufacturing method thereof will be described below with reference to the accompanying drawings. First, as shown in FIG. 11, a p-type semiconductor substrate 1S is prepared by introducing p-type impurities, such as boron (B), as a conductive impurity. Then, as shown in FIG. 12, an n-type semiconductor region NR is formed over the p-type semiconductor substrate 1S. The n-type semiconductor region NR can be formed by using, for example, epitaxial growth. The n-type semiconductor region NR has n-type impurities, such as phosphorus (P), introduced thereinto as a conductive impurity.

Subsequently, as shown in FIG. 13, a p-type semiconductor region PR is formed over the n-type semiconductor region NR. The p-type semiconductor region PR can be formed, for example, by introducing p-type impurities, such as boron (B), into the n-type semiconductor region NR by ion implantation, and then by diffusing the introduced p-type impurities by the heat treatment. In this way, the PNP injection can be formed by the semiconductor substrate 1S, the n-type semiconductor region NR, and the p-type semiconductor region PR.

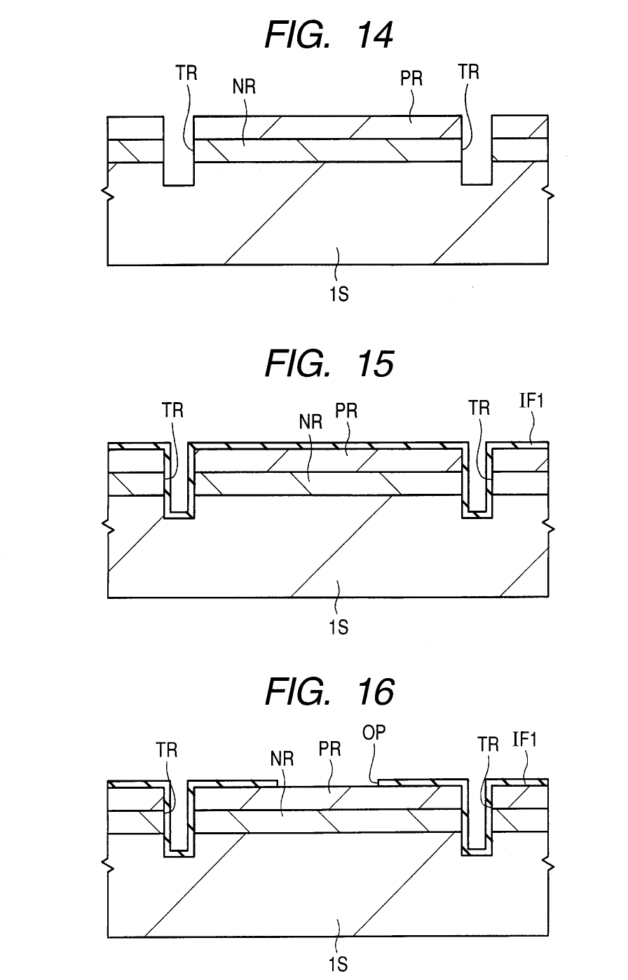

Then, as shown in FIG. 14, the trenches TR (trenchs) are formed by use of the photolithography technique and the etching technique. The trench TR is formed to reach the inside of the semiconductor substrate 1S from the surface of the p-type semiconductor region PR through the p-type semiconductor region PR and the n-type semiconductor region NR. Thus, the active region interposed between the pair of trenches TRs is isolated.

Therefore, as shown in FIG. 15, the protective insulating film IF1 is formed over the p-type semiconductor region PR including the inner walls (side surfaces and bottom) of each trench TR. The protective insulating film IF1 can be comprised of, for example, a silicon oxide film, a silicon nitride film, a PSG film which is a glassy film provided by adding phosphorus into a silicon oxide film, or the like.

Then, as shown in FIG. 16, the opening OP is formed in the protective insulating film IF1 by use of the photolithography technique and the etching technique. The opening OP is formed to open a part of the active region interposed between the pair of trenches TRs, and to expose a part of the p-type semiconductor region PR.

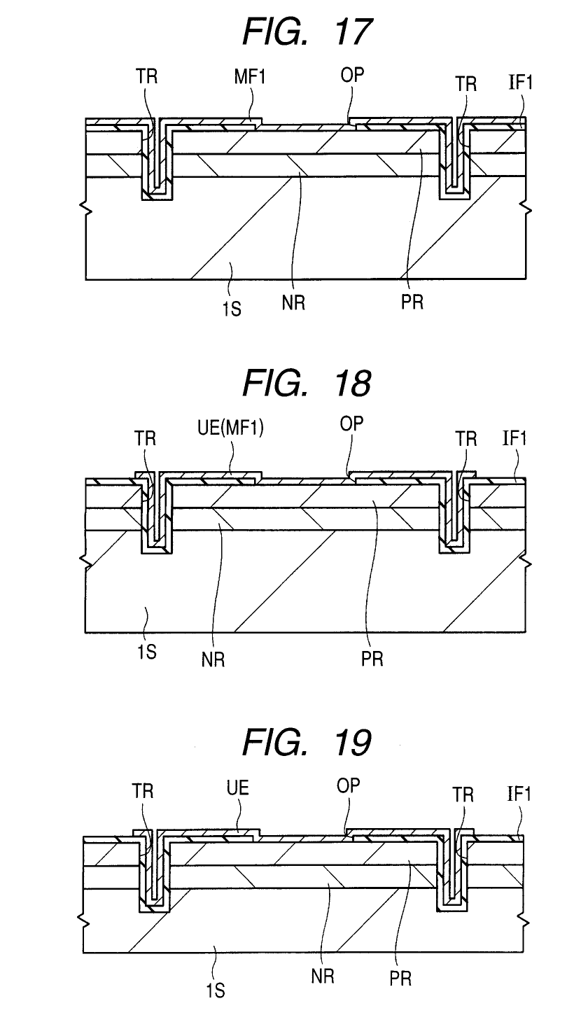

Subsequently, as shown in FIG. 17, a conductive film MF1 (light blocking film) containing metal is formed over the protective insulating film IF1 including the opening OP. The conductive film MF1 is comprised of, for example, a film having a light blocking effect, such as an aluminum-silicon film, and can be formed, for example, by sputtering. The conductive film MF1 is formed in contact with the p-type semiconductor region PR in the opening OP so as to cover the inner walls of the trenches TRs.

As shown in FIG. 18, a conductive film MF1 is patterned by use of the photolithography and etching. The patterning of the conductive film MF1 is performed such that the conductive film MF1 extends from the inside of the opening OP to cover the inner wall of the trench TR. Thus, the upper electrode UE can be formed so as to be in contact with the p-type semiconductor region PR in the opening OP and to cover the inner wall of each trench TR. That is, the inner wall of the trench TR is covered with the upper electrode UE (light blocking film) having the light blocking effect. Thus, even when light is applied to the inside of the trench TR, the light can be prevented from entering the p-n injection formed at the boundary between the n-type semiconductor region NR and the p-type semiconductor region PR, from the inner wall of the trench TR. This can suppress the occurrence of the photoelectric effect due to the p-n injection.

Then, as shown in FIG. 19, the back surface of the semiconductor substrate 1S is polished (back-ground) to make the semiconductor substrate 1S thinner. Thereafter, as shown in FIG. 8, a back electrode BE is formed at the back surface of the semiconductor substrate 1S. The back electrode BE is formed of, for example, a gold film by use of vapor deposition.

As mentioned above, the bidirectional Zener diode IZD of the first embodiment can be manufactured. In the bidirectional Zener diode IZD of the first embodiment, the inner surface of each trench TR is covered with the upper electrode UE (light blocking film) having the light blocking effect. Thus, even when light is applied to the bidirectional Zener diode IZD, the light can be prevented from entering the p-n junction formed at the boundary between the n-type semiconductor region NR and the p-type semiconductor region PR from the inner wall of the trench TR. According to the first embodiment, the leak current due to the photoelectric effect can be reduced.

### Second Embodiment

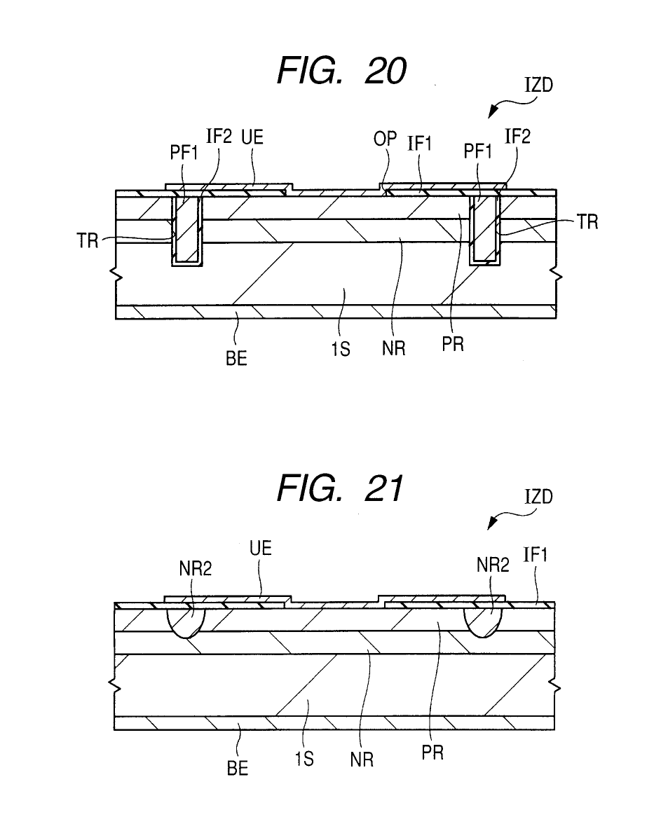

A second embodiment of the invention will describe an example in which the inside of the trench TR is filled with a filling membrane. FIG. 20 shows a cross-sectional view of a bidirectional Zener diode IZD according to the second embodiment. The bidirectional Zener diode IZD of the second embodiment shown in FIG. 20 has substantially the same structure as that of the bidirectional Zener diode IZD of the first embodiment shown in FIG. 8, and different points therebetween will be described below. The feature of the bidirectional Zener diode IZD of the second embodiment is that as shown in FIG. 20, the inside of the trench TR is filled with the polysilicon film PF1 via the insulating film IF2 made of, for example, a silicon oxide film.

Since the inside of the trench TR is filled with the polysilicon film PF1, the surface of the trench TR is aligned with the surface of the p-type semiconductor region PR. As a result, the flatness is improved over the surface of the trench TR filled with the polysilicon film PF1 and the surface of the p-type semiconductor region PR, which advantageously facilitates formation of the protective insulating film IF1 over the p-type semiconductor region PR including the trench TR.

Although the second embodiment has described the example in which the inside of the trench TR is filled with the polysilicon film PF1 via the insulating film IF2, only the insulating film may be embedded in the trench TR.

Also, in the bidirectional Zener diode IZD of the second embodiment, an upper electrode UE extends from the inside of an opening OP to cover the trench TR (isolation region), like the bidirectional Zener diode IZD of the first embodiment. Thus, even when light is applied to the bidirectional Zener diode IZD, the light can be prevented from entering the p-n junction formed at the boundary between the n-type semiconductor region NR and the p-type semiconductor region PR from the inner wall of the trench TR. Thus, the occurrence of the photoelectric effect in the p-n junction can be suppressed. That is, the bidirection Zener diode IZD of the second embodiment can reduce the leak current flowing from the n-type semiconductor region NR to the p-type semiconductor region PR due to the photoelectric effect in the p-n junction. This means that, for example, the current passing through the light-emitting diode LED coupled in parallel to the bidirectional Zener diode IZD can be ensured to reduce the loss of the current. Since the leak current at the bidirectional Zener diode IZD can be reduced, the Zener diode IZD can improve the efficiency of use of current for emission of light from the light-emitting diode LED to thereby reduce the useless current not contributing to the light emission of the light-emitting diode LED. In this way, the bidirectional Zener diode IZD of the second embodiment can reduce the leak current due to the photoelectric effect, and as a result, can improve the efficiency of use of current at the diode LED.

The bidirectional Zener diode IZD of the second embodiment has the structure described above, and a manufacturing method thereof is substantially the same as that of the first embodiment. Specifically, the steps shown in FIGS. 11 to 14 are performed. And, after forming the insulating film IF2 on the surface of the p-type semiconductor region PR including the inner wall of the trench TR, the polysilicon film PF1 is formed to fill the trenches TRs. Subsequently, unnecessary parts of the polysilicon film PF1 and the insulating film IF2 formed on the surface of the p-type semiconductor region PR are removed, so that the insulating film IF2 and the polysilicon film PF1 are left only in the trenches TRs. The following steps are substantially the same as those of the first embodiment. As mentioned above, the bidirectional Zener diode IZD of the second embodiment can be manufactured.

### Third Embodiment

A third embodiment of the invention will describe an example in which an isolation region is formed of the semiconductor region. FIG. 21 is a cross-sectional view showing the structure of a bidirectional Zener diode IZD according to the third embodiment. The bidirectional Zener diode IZD of the third embodiment shown in FIG. 21 has substantially the same structure as that of the bidirectional Zener diode IZD of the first embodiment shown in FIG. 8, and different points therebetween will be described below. The feature of the bidirectional Zener diode IZD of the third embodiment is that as shown in FIG. 21, the isolation region is formed of an n-type semiconductor region NR2. The n-type semiconductor region NR2 is formed to reach the n-type semiconductor region NR from the surface of the p-type semiconductor region PR. The concentration of impurities in the n-type semiconductor region NR2 is higher than that of the n-type semiconductor region NR.

As mentioned above, in the third embodiment, the isolation region is formed not from the trench TR like the first and second embodiments, but from the n-type semiconductor region NR2. This has an advantage that the step of forming the trench TR can be omitted. Since no trench TR is formed, the surface of the p-type semiconductor region PR is aligned with the surface of the n-type semiconductor region NR2 serving as the isolation region, which advantageously facilitates formation of the protective insulating film IF1 over the p-type semiconductor region PR including the n-type semiconductor region NR2 (isolation region).

Also in the bidirectinal Zener diode IZD of the third embodiment, like the bidirectinal Zener diode IZD of the first embodiment, the upper electrode UE extends from the inside of the opening OP to cover the isolation region (n-type semiconductor region NR2). Even when the light is applied to the bidirectional Zener diode IZD, the light can be prevented from entering the p-n junction formed at the boundary between the n-type semiconductor region NR and the p-type semiconductor region PR. Thus, the occurrence of the photoelectric effect at the p-n junction can be prevented. That is, the bidirectional Zener diode IZD of the third embodiment can also reduce the leak current flowing from the n-type semiconductor region NR to the p-type semiconductor region PR due to the photoelectric effect in the p-n junction. This means that, for example, the current passing through the light-emitting diode LED coupled in parallel to the bidirectional Zener diode IZD can be ensured to reduce the loss of the current. Since the leak current at the bidirectional Zener diode IZD can be reduced, the Zener diode IZD can improve the efficiency of use of current for emission of light from the light-emitting diode LED to thereby reduce the useless current not contributing to the light emission of the light-emitting diode LED. In this way, the bidirectional Zener diode IZD of the third embodiment can also reduce the leak current due to the photoelectric effect, and as a result, can improve the efficiency of use of current at the diode LED.

The bidirectional Zener diode IZD of the third embodiment has the structure described above, and a manufacturing method thereof is substantially the same as that of the first embodiment. Specifically, the steps shown in FIGS. 11 to 13 are performed. Then, instead of the step shown in FIG. 14, the n-type semiconductor region NR2 serving as the isolation region is formed by use of photolithography and ion implantation. The following steps are substantially the same as those of the first embodiment except that the isolation region becomes the n-type semiconductor region NR2 instead of the trench TR. As mentioned above, the bidirectional Zener diode IZD of the third embodiment can be manufactured.

### Fourth Embodiment

Although the first to third embodiments have described the bidirectional Zener diode IZD, a fourth embodiment of the invention will describe an example of application of the invention to the Zener diode ZD. As described in the first embodiment, when using the light-emitting diodes LEDs coupled in the form of a matrix, the bidirectional Zener diode IZD for protecting the light-emitting diode LED from the surge voltage is desirably coupled in parallel to the corresponding light-emitting diode LED for the purpose of suppressing the sneak current. When using the single light-emitting diode LED, the sneak current is not generated, and thus the Zener diode ZD for protecting the diode LED from the surge voltage is supposed to be coupled in anti-parallel to the light-emitting diode LED. Thus, the light-emitting diode LED and the Zener diode ZD are proposed to be mounted in one package. In this case, the Zener diode ZD is also required to reduce the leak current due to the photoelectric effect. Thus, the technical ideas given in the description of the bidirectional Zener diodes IZDs of the first to third embodiments can be applied to the Zener diode ZD, too.

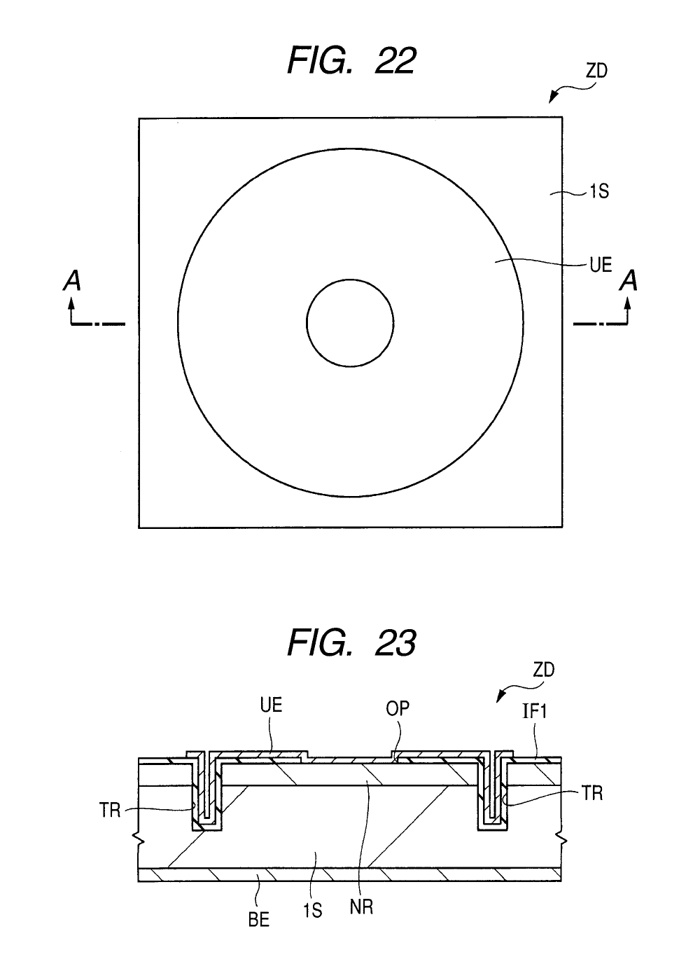

Now, the fourth embodiment of the invention will describe an example in which the invention is applied to the Zener diode ZD. FIG. 22 is a plan view of the Zener diode ZD in the fourth embodiment as viewed from the upper surface. Referring to FIG. 22, a circular upper electrode UE is formed over a rectangular semiconductor substrate 1S. Now, the detailed structure of the Zener diode ZD in the fourth embodiment will be described below with reference to FIG. 23.

FIG. 23 is a cross-sectional view taken along the line A-A of FIG. 22. As shown in FIG. 23, a back electrode BE made of, for example, a gold film is formed at the back surface (lower surface) of the p-type semiconductor substrate 1S. In contrast, an n-type semiconductor region NR is formed over the upper surface of the p-type semiconductor substrate 1S. Thus, the p-n injection of the Zener diode ZD is formed by the semiconductor substrate 1S and n-type semiconductor region NR.

A pair of trenches TR is formed to reach the inside of the semiconductor substrate 1 through the n-type semiconductor region NR from the surface of the n-type semiconductor region NR. The region interposed between the pair of trenches TRs is an active region serving as the Zener diode ZD. That is, in the trench Zener diode ZD, the active region is isolated by the pair of the trenches TRs, and the Zener diode ZD is formed in the isolated active region.

A protective insulating film IF1 is formed over the surface of the n-type semiconductor region NR with such trenches TRs formed therein. Specifically, the protective insulating film IF1 is formed over the surface of the n-type semiconductor region NR including the inner walls of the trenches TRs. The protective insulating film IF1 is comprised of, for example, a silicon oxide film, a silicon nitride film, a PSG film which is a glassy film provided by adding phosphorus into a silicon oxide film, or the like.

An opening OP is formed in the protective insulating film IF1, and an upper electrode UE is formed over the protective insulating film IF1 including the opening OP. Specifically, the opening OP is formed in the active region interposed between the pair of trenches TRs. The n-type semiconductor region NR is exposed to the bottom of the opening OP. In the fourth embodiment, the upper electrode UE is formed to extend from the inside of the opening OP over the protective insulating film IF1 covering the inner walls of the trenches TRs. Thus, the upper electrode UE is brought into contact with the n-type semiconductor region NR exposed to the bottom of the opening OP. The upper electrode UE is comprised of a conductive film, such as a metal film or a metal compound film, for example, an aluminum-silicon film.

Also, in the fourth embodiment, the upper electrode UE extends from the inside of the opening OP to cover the trench TR (isolation region). That is, as shown in FIG. 23, the upper electrode UE is formed so as to cover the inner walls of the trenches TRs in the Zener diode ZD of the fourth embodiment. The upper electrode UE is comprised of a conductive film containing metal, for example, an aluminum-silicon film, and thus has the light blocking effect. That is, in the Zener diode ZD of the fourth embodiment, the inner walls of the trenches TRs are covered with the upper electrode UE (light blocking film) having the light blocking effect. Even when the light is applied to the Zener diode ZD, the light can be prevented from entering the p-n junction formed at the boundary between the n-type semiconductor region NR and the semiconductor substrate 1S from the inner wall of the trench TR. Thus, the occurrence of the photoelectric effect at the p-n junction can be prevented. That is, in the Zener diode ZD of the fourth embodiment, the leak current flowing from the n-type semiconductor region NR to the semiconductor substrate 1S can be reduced in the p-n junction due to the photoelectric effect. This means that the current passing through the light-emitting diode LED coupled in anti-parallel to the Zener diode ZD can be ensured to reduce the loss of the current. Since the leak current at the Zener diode ZD can be reduced, the Zener diode ZD can improve the efficiency of use of current for emission of light from the light-emitting diode LED to thereby reduce the useless current not contributing to the light emission of the light-emitting diode LED. In this way, the Zener diode ZD of the fourth embodiment can reduce the leak current due to the photoelectric effect, and as a result, can improve the efficiency of use of current at the diode LED.

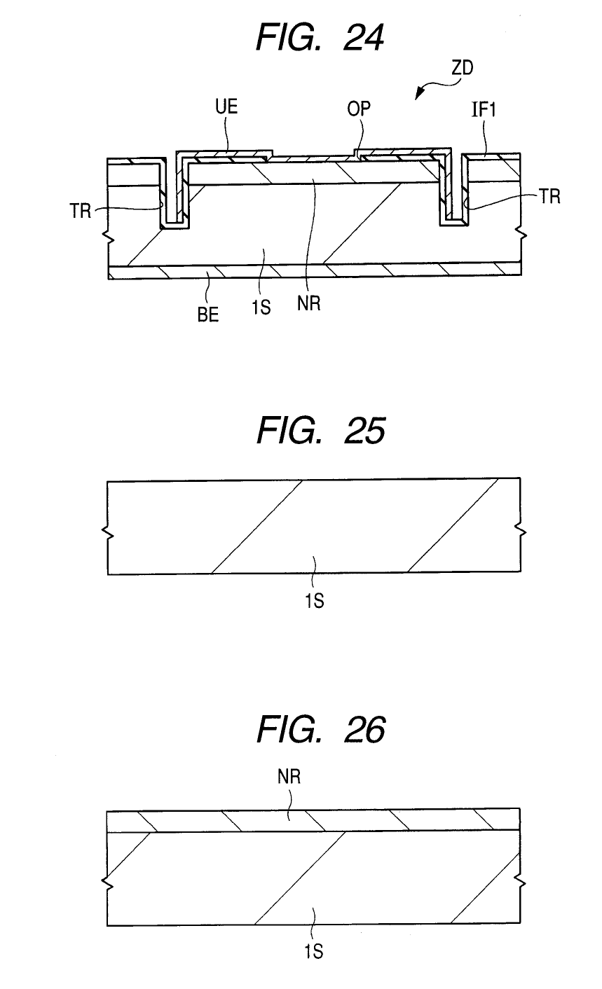

Next, a modified example of the Zener diode ZD in the fourth embodiment will be described below. FIG. 24 is a cross-sectional view showing the structure of the Zener diode ZD in the modified example. The Zener diode ZD shown in FIG. 24 has substantially the same structure as the Zener diode ZD shown in FIG. 23, and different points thereof will be described below. Specifically, in the Zener diode ZD shown in FIG. 23, the upper electrode UE is formed to cover the inner walls of the trenches TRs (side faces on both sides). In contrast, in the Zener diode ZD shown in FIG. 24, the upper electrode UE extends from the inside of the opening OP thereby to cover at least one side (a side surface of one side) of both sides of the trench TR, in contact with the active region with the Zener diode ZD formed therein. With this arrangement, the light can be prevented from entering the p-n junction formed at the boundary between the n-type semiconductor region NR and the semiconductor substrate 1S, from the inner wall of the trench TR. Thus, the occurrence of photoelectric effect in the p-n junction can be suppressed. That is, when no light is applied to the p-n junction in the active region formed on the inner one of both sides of the trench TR, the leak current due to the photoelectric effect can be reduced. From this point, in the Zener diode ZD of the fourth embodiment, like the Zener diode ZD shown in FIG. 24, the upper electrode UE may be formed to cover at least one side of both sides of the trench TR (side surface on one side) in contact with the active region with the bidirectional Zener diode ZD formed therein.

The Zener diode ZD of the fourth embodiment has the structure described above, and a manufacturing method thereof will be described below with reference to the accompanying drawings. First, as shown in FIG. 25, p-type impurities, such as boron (B), are introduced into a semiconductor substrate as a conductive impurity to prepare a p-type semiconductor substrate 1S. Then, as shown in FIG. 26, an n-type semiconductor region NR is formed over the p-type semiconductor substrate 1S. The n-type semiconductor region NR can be formed, for example, by epitaxial growth. The n-type semiconductor region NR has n-type impurities, such as phosphorus (P), introduced thereinto as a conductive impurity. In this way, the p-n junction can be formed by the semiconductor substrate 1S and the n-type semiconductor region NR.

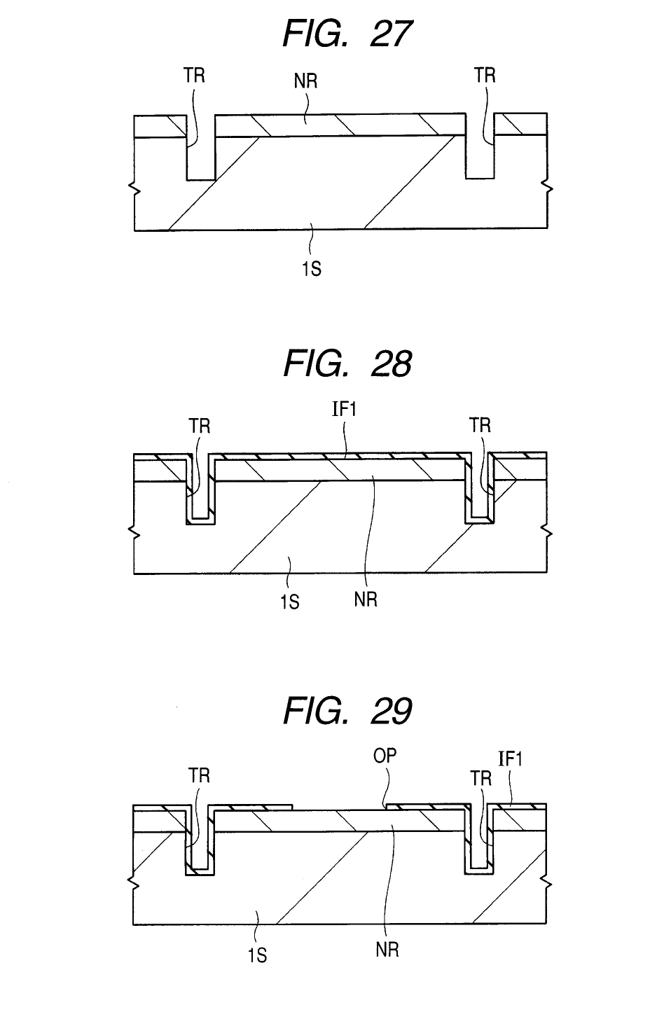

Then, as shown in FIG. 27, the trenches TR (grooves) are formed by use of the photolithography technique and the etching technique. The trenches TR are formed to reach the inside of the semiconductor substrate 1S from the surface of the n-type semiconductor region NR, through the n-type semiconductor region NR. Thus, an active region interposed between the pair of trenches TRs is isolated.

Thereafter, as shown in FIG. 28, the protective insulating film IF1 is formed over the n-type semiconductor region NR including the inner walls (side surfaces and bottom) of the trenches TRs. The protective insulating film IF1 is comprised of, for example, a silicon oxide film, a silicon nitride film, a PSG film which is a glassy film provided by adding phosphorus into a silicon oxide film, or the like.

Then, as shown in FIG. 29, the opening OP is formed in the protective insulating film IF1 by use of the photolithography technique and the etching technique. The opening OP is formed to open a part of the active region interposed between a pair of trenches TRs and to expose a part of the n-type semiconductor region NR.

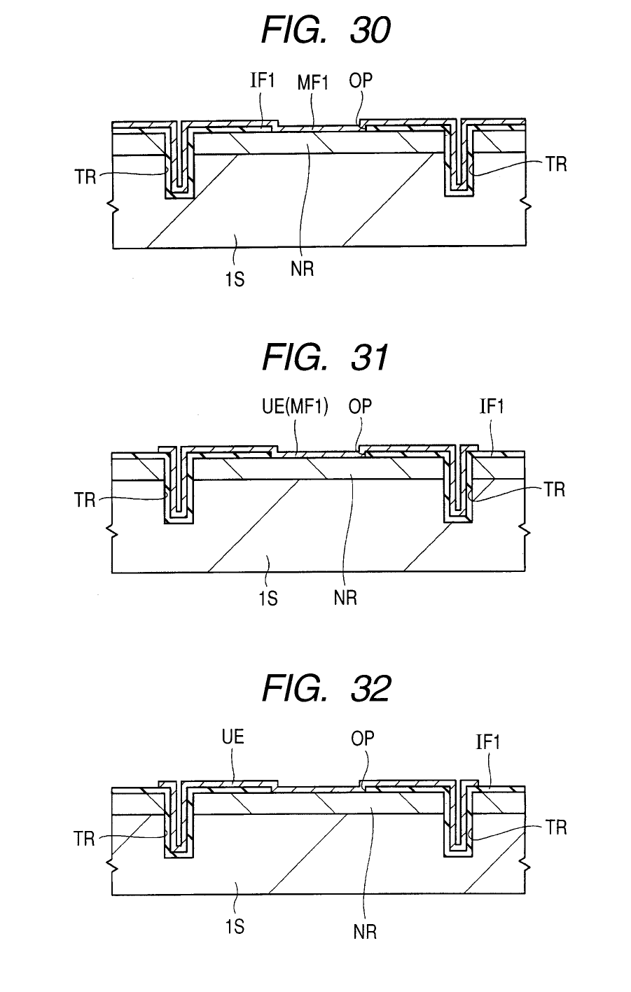

Subsequently, as shown in FIG. 30, the conductive film MR1 (light blocking film) containing metal is formed over the protective insulating film IF1 including the inside of the opening OP. The conductive film MF1 is comprised of a film having the light blocking effect, for example, an aluminum-silicon film, and thus can be formed, for example, by sputtering. The conductive film MF1 is formed in contact with the n-type semiconductor region NR in the opening OP to cover the inner walls of the trenches TRs.

And as shown in FIG. 31, the conductive film MF1 is patterned by the photolithography technique and the etching technique. The patterning of the conductive film MF1 is performed such that the conductive film MF1 extends from an inside of the opening OP to cover the inner wall of the trench TR. Thus, the upper electrode UE can be formed in contact with the n-type semiconductor region NR in the opening OP to cover the inner walls of the trenches TRs. That is, the inner wall of each trench TR is covered with the upper electrode UE (light blocking film) having the light blocking effect. Even when the light is applied to the inside of the trench TR, the light can be prevented from entering the p-n junction formed at the boundary between the n-type semiconductor region NR and the semiconductor substrate 1S, from the inner wall of the trench TR. Thus, the occurrence of the photoelectric effect in the p-n junction can be suppressed.

Then, as shown in FIG. 32, the back surface of the semiconductor substrate 1S is ground (back-ground) to make the semiconductor substrate 1S thin. Thereafter, as shown in FIG. 23, the back electrode BE is formed at the back side of the semiconductor substrate 1S. The back electrode BE can be comprised of, for example, a gold film, by use of vapor deposition.

As mentioned above, the Zener diode ZD of the fourth embodiment can be manufactured. In the Zener diode ZD of the fourth embodiment, the inner wall of each trench TR is covered with the upper electrode UE (light blocking film) having the light blocking effect. Even when the light is applied to the Zener diode ZD, the light can be prevented from entering the p-n junction formed at the boundary between the n-type semiconductor region NR and the semiconductor substrate 1S from the inner wall of the trench TR. Thus, according to the fourth embodiment, the leak current due to the photoelectric effect can be reduced.

### Fifth Embodiment

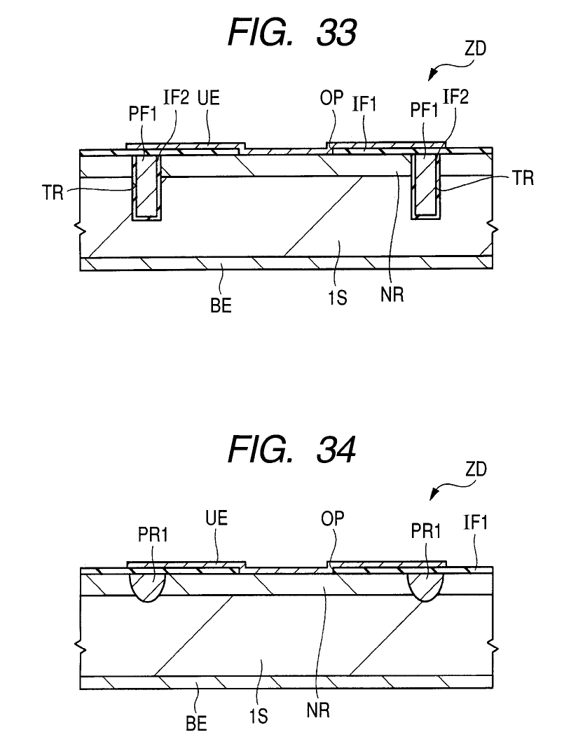

A fifth embodiment of the invention will describe an example in which the inside of the trench TR is filled with a filling film. FIG. 33 is a cross-sectional view showing the structure of a Zener diode ZD of the fifth embodiment. The Zener diode ZD of the fifth embodiment shown in FIG. 33 has substantially the same structure as that of the Zener diode ZD of the fourth embodiment shown in FIG. 23, and thus only different points between them will be described below. The feature of the Zener diode ZD of the fifth embodiment is that as shown in FIG. 33, the inside of the trench TR is filled with a polysilicon film PF1 via an insulating film IF2 made of, for example, a silicon oxide film.

Thus, the inside of the trench TR is filled with the polysilicon film PF1, so that the surface of the trench TR is aligned with the surface of the n-type semiconductor region NR. As a result, the flatness is improved over the surface of the trench TR filled with the polysilicon film PF1 and the surface of the n-type semiconductor region NR, which advantageously facilitates formation of the protective insulating film IF1 over the n-type semiconductor region NR including the trench TR.

Although the fifth embodiment has described an example in which the inside of the trench TR is filled with the polysilicon film via the insulating film IF2, only the insulating film may be embedded in the trench TR.

Also, in the Zener diode ZD of the fifth embodiment, like the Zener diode ZD of the fourth embodiment, the upper electrode UE extends from the inside of the opening OP to cover the trench TR (isolation region). Even when the light is applied to the Zener diode ZD, the light can be prevented from entering the p-n junction formed at the boundary between the n-type semiconductor region NR and the semiconductor substrate 1S from the inner wall of the trench TR. Thus, the occurrence of the photoelectric effect in the p-n junction can be suppressed. That is, the Zener diode ZD of the fifth embodiment can also reduce the leak current flowing from the n-type semiconductor region NR to the semiconductor substrate 1S due to the photoelectric effect in the p-n junction. This means that, for example, the current passing through the light-emitting diode coupled in anti-parallel to the Zener diode ZD can be ensured to thereby reduce the loss of the current. Since the leak current at the Zener diode ZD can be reduced, the Zener diode ZD can improve the efficiency of use of current for emission of light from the light-emitting diode LED to thereby reduce the useless current not contributing to the light emission of the light-emitting diode LED. In this way, the Zener diode ZD of the fifth embodiment can also reduce the leak current due to the photoelectric effect, and as a result, can improve the efficiency of use of current at the diode LED.

The Zener diode IZD of the fifth embodiment has the structure described above, and a manufacturing method thereof is substantially the same as that of the fourth embodiment. Specifically, steps shown in FIGS. 25 to 27 are performed. Then, the insulating film IF2 is formed over the surface of the n-type semiconductor region NR including the inner wall of each trench TR, and then the polysilicon film PF1 is formed to fill the trenches TRs. Subsequently, unnecessary parts of the polysilicon film PF1 and the insulating film IF2 formed over the surface of the n-type semiconductor region NR are removed, so that the insulating film IF2 and the polysilicon film PF1 are left only in the trench TR. The following steps are substantially the same as those of the fourth embodiment. As mentioned above, the Zener diode ZD of the fifth embodiment can be manufactured.

### Sixth Embodiment

A sixth embodiment of the invention will describe an example in which an isolation region is comprised of a semiconductor region. FIG. 34 is a cross-sectional view showing the structure of a Zener diode ZD of the sixth embodiment. The structure of the Zener diode ZD in the sixth embodiment shown in FIG. 34 has substantially the same structure as that of the Zener diode ZD in the fourth embodiment shown in FIG. 23, and thus different points therebetween will be described below. The feature of the Zener diode ZD of the sixth embodiment is that as shown in FIG. 34, the isolation region is comprised of the p-type semiconductor region PR1. The p-type semiconductor region PR1 is formed to reach the inside of the semiconductor substrate 1S from the surface of the n-type semiconductor region NR. The concentration of impurities in the p-type semiconductor region PR1 is higher than that of the semiconductor substrate 1S.

As mentioned above, in the sixth embodiment, the isolation region is not formed from the trench TR, unlike the fourth and fifth embodiments, and thus formed from the p-type semiconductor region PR1. This has an advantage that the step for forming the trench TR can be omitted. Further, since no trench TR is formed, the surface of the n-type semiconductor region NR is aligned with the surface of the p-type semiconductor region PR1 serving as the isolation region, which advantageously facilitates the formation of the protective insulating film IF1 over the n-type semiconductor region NR including the p-type semiconductor region PR1 (isolation region).

In the Zener diode ZD of the sixth embodiment, like the Zener diode ZD of the fourth embodiment, the upper electrode UE extends from the inside of the opening OP to cover the isolation region (p-type semiconductor region PR1). Thus, even when light is applied to the Zener diode ZD, the light can be prevented from entering the p-n junction formed at the boundary between the p-type semiconductor region PR1 and the n-type semiconductor region NR, and the p-n junction formed at the boundary between the n-type semiconductor region NR and the semiconductor substrate 1S. Thus, the occurrence of the photoelectric effect in the p-n junction can be suppressed. This means that the current flowing through the light-emitting diode LED coupled in anti-parallel to the Zener diode ZD can be ensured to reduce the loss of current. Since the leak current at the Zener diode ZD can be reduced, the Zener diode ZD can improve the efficiency of use of current for emission of light from the light-emitting diode LED to thereby reduce the useless current not contributing to the light emission of the light-emitting diode LED. In this way, the Zener diode ZD of the sixth embodiment can also reduce the leak current due to the photoelectric effect, and as a result, can improve the efficiency of use of current at the diode LED.

The Zener diode ZD of the sixth embodiment has the structure described above, and a manufacturing method thereof is substantially the same as that of the fourth embodiment. Specifically, the steps shown in FIGS. 25 and 26 are performed. Then, the p-type semiconductor region PR1 serving as an isolation region is formed by use of the photolithography technique and the ion implantation method, instead of the step shown in FIG. 27. The following steps are substantially the same as those of the fourth embodiment except that the isolation region is the p-type semiconductor region PR1 instead of the trench TR. As mentioned above, the Zener diode ZD of the sixth embodiment can be manufactured.

### Seventh Embodiment

The first to third embodiments have described the device structures of the bidirectional Zener diodes, and the fourth to sixth embodiments has described the device structures of the Zener diodes. The seventh embodiment will describe a package structure including the bidirectional Zener diode described in the first to third embodiments and the light-emitting diode which are mounted in one package, or a package structure including the Zener diode described in the fourth to sixth embodiments and the light-emitting diode which are mounted in one package.

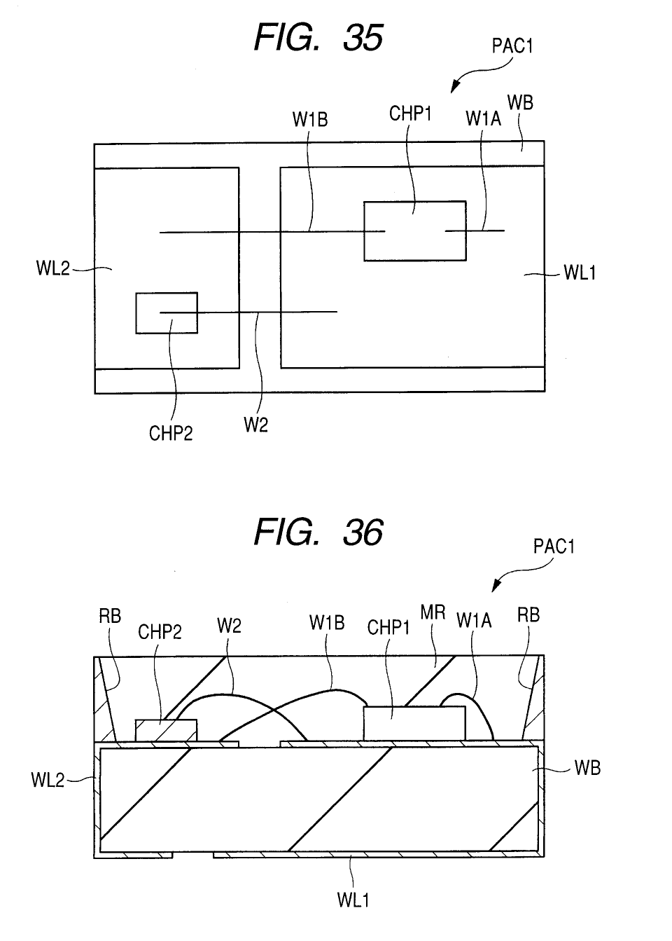

FIG. 35 is a plan view of a semiconductor device (package structure) in the seventh embodiment. As shown in FIG. 35, a package PAC1 (semiconductor device) of the seventh embodiment includes a rectangular wiring board WB over which a wiring WL1 and a wiring WL2 are formed. The wiring WL1 and the wiring WL2 are electrically separated from each other. A semiconductor chip CHP1 is mounted over the wiring WL1. The semiconductor chip CHP1 is coupled to the wiring WL1 via a wire W1A. Further, the semiconductor chip CHP1 is coupled to the wiring WL2 via the wire W1B. The light-emitting diode is formed in the semiconductor chip CHP1. A semiconductor chip CHP2 is mounted over the wiring WL2, and coupled to the wiring WL1 via a wire W2. The bidirectional Zener diode or the Zener diode is formed in the semiconductor chip CHP2. Thus, the semiconductor chip CHP2 has a back electrode coupled to the wiring WL2.

FIG. 36 is a cross-sectional view showing one section of the package PAC1 shown in FIG. 35. In FIG. 36, the wiring WL1 and the wiring WL2 are formed at the wiring board WB, the semiconductor chip CHP1 is mounted over the wiring WL1, and the semiconductor chip CHP2 is mounted over the wiring WL2. The semiconductor chip CHP1 is coupled to the wiring WL1 via the wire W1A, and the semiconductor chip CHP1 is also coupled to the wiring WL2 via the wiring W1B. In contrast, the semiconductor chip CHP2 has a back electrode coupled to the wiring WL2, and the semiconductor chip CHP2 is coupled to the wiring WL1 via the wire W2. At this time, the light-emitting diode is formed in the semiconductor chip CHP1, and the bidirectional Zener diode or the Zener diode is formed in the semiconductor chip CHP2. Reflective boards RBs are formed above the wiring board WB, and the semiconductor chip CHP1 and the semiconductor chip CHP2 are sealed with resin MR containing fluorescent material.

The circuit shown in each of FIGS. 1 and 3 is formed by the thus-structured package PAC1. When current passes through between the wirings WL1 and WL2 in the package PAC1, the current is allowed to flow through the light-emitting diode formed in the semiconductor chip CHP1, causing the diode to emit light. For example, the light-emitting diode formed in the semiconductor chip CHP1 is a blue light-emitting diode, and emits blue light. The blue light emitted from the light-emitting diode is converted into white light by being applied to the fluorescent material contained in the resin MR. In this way, the white light can be applied from the package PAC1. At this time, since the package PAC1 is provided with the reflective board RB, the blue light emitted from the light-emitting diode is effectively converted into the white light.

For example, suppose that the surge voltage is applied to the light-emitting diode from the outside. In this case, the surge voltage is also applied to the bidirectional Zener diode (simply, the Zener diode) coupled in anti-parallel to the light-emitting diode. Thus, when the surge voltage exceeds the breakdown voltage of the bidirectional Zener diode (Zener diode), the breakdown of the bidirectional Zener diode (Zener diode) occurs to absorb the surge voltage, which is converted into a small Zener voltage. As a result, the only small Zener voltage is applied to the light-emitting diode, which can protect the light-emitting diode from the surge voltage.

The semiconductor chip CHP2 used in the seventh embodiment is provided with the bidirectional Zener diode of any one of the first to third embodiments, or the Zener diode of any one of the fourth to sixth embodiments. Thus, even when the semiconductor chip CHP2 is mounted together with the semiconductor chip CHP1 in one package, the leak current due to the photoelectric effect can be reduced in the semiconductor chip CHP2. This means that the current flowing through the light-emitting diode formed in the semiconductor chip CHP1 can be ensured to reduce the loss of current. Since the leak current due to the photoelectric effect can be reduced in the semiconductor chip CHP2, the efficiency of use of current for emission of light from the light-emitting diode formed in the semiconductor chip CHP1 can be improved to thereby lessen useless current not contributing to the light emission from the light-emitting diode LED. The semiconductor chip CHP1 and the semiconductor chip CHP2 are mounted in one package, so that the package PAC1 of the seventh embodiment can reduce its size. That is, the seventh embodiment can provide the package PAC1 that achieves both the low power consumption and the reduction in size.

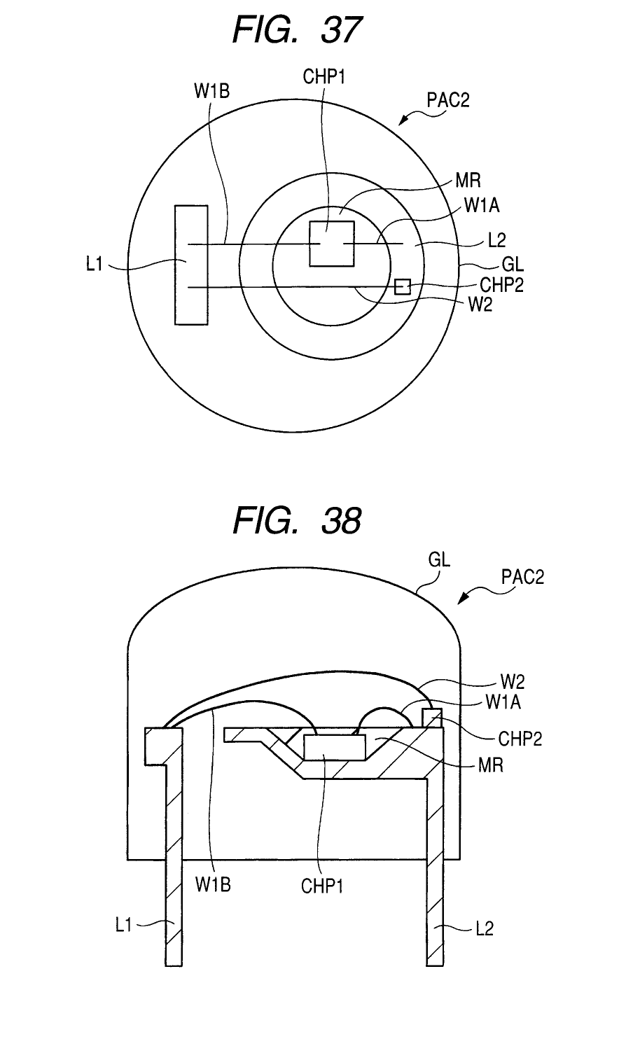

Next, another package PAC2 (semiconductor device) of the seventh embodiment will be described below. FIG. 37 is a plan view showing another semiconductor device (package structure) of the seventh embodiment. As shown in FIG. 37, the package PAC2 (semiconductor device) of the seventh embodiment includes a rectangular lead L1 and a circular lead L2. The semiconductor chip CHP1 and the semiconductor chip CHP2 are mounted over the circular lead L2. The rectangular lead L1 is electrically isolated from the circular lead L2. The semiconductor chip CHP1 and the lead L2 which are mounted over the circular lead L2 are coupled to each other via the wire W1A, and the semiconductor chip CHP1 and the lead L1 are coupled to each other via the wire W1B. The semiconductor chip CHP1 has the light-emitting diode formed therein. The semiconductor chip CHP1 is sealed with the resin MR containing fluorescent material. In contrast, the semiconductor chip CHP2 mounted over the circular lead L2 is coupled to the lead L1 via the wire W2. The semiconductor chip CHP2 has the bidirectional Zener diode, or the Zener diode formed therein. Thus, in the semiconductor chip CHP2, the back electrode is coupled to the lead L2. The thus-structured leads L1 and L2 are covered with the transparent glass GL.

FIG. 38 is a cross-sectional view showing one section of the package PAC2 shown in FIG. 37. Referring to FIG. 38, the lead L1 and the lead L2 are disposed spaced apart from each other, whereby the semiconductor chip CHP1, and the semiconductor chip CHP2 are mounted on the lead L2. The semiconductor chip CHP1 is disposed in a recess formed in the lead L2, and sealed with resin MR containing fluorescent material. On the other hand, the semiconductor chip CHP2 is disposed in an end region of the lead L2. The semiconductor chip CHP1 is coupled to the lead L2 via the wire W1A, and coupled to the lead L1 via the wire W1B. The semiconductor chip CHP2 is coupled to the lead L1 via the wire W2. The leads L1 and L2 are sealed with the glass GL.

The circuit shown in each of FIGS. 1 and 3 is formed by the thus-structured package PAC2. When current passes through between the leads L1 and L2 in the package PAC2, the current is allowed to flow through the light-emitting diode formed in the semiconductor chip CHP1, causing the diode to emit light. For example, the light-emitting diode formed in the semiconductor chip CHP1 is a blue light-emitting diode, and emits blue light. The blue light emitted from the light-emitting diode is converted into white light by being applied to the fluorescent material contained in the resin MR. In this way, the white light can be applied from the package PAC1.

For example, suppose that the surge voltage is applied to the light-emitting diode from the outside. In this case, the surge voltage is also applied to the bidirectional Zener diode (Zener diode) coupled in anti-parallel to the light-emitting diode. Thus, when the surge voltage exceeds the breakdown voltage of the bidirectional Zener diode (Zener diode), the breakdown of the bidirectional Zener diode (Zener diode) occurs to absorb the surge voltage, which is converted into a small Zener voltage. As a result, the only small Zener voltage is applied to the light-emitting diode, which can protect the light-emitting diode from the surge voltage.

The semiconductor chip CHP2 used in the seventh embodiment is provided with the bidirectional Zener diode of any one of the first to third embodiments, or the Zener diode of any one of the fourth to sixth embodiments. Thus, even when the semiconductor chip CHP2 is mounted together with the semiconductor chip CHP1 in one package, the leak current due to the photoelectric effect can be reduced in the semiconductor chip CHP2. This means that the current passing through the light-emitting diode formed in the semiconductor chip CHP1 can be ensured to reduce the loss of the current. Since the leak current due to the photoelectric effect in the semiconductor chip CHP2 can be reduced, the efficiency of use of current for emission of light from the light-emitting diode formed in the chip CHP1 can be improved to thereby reduce the useless current not contributing to the light emission of the light-emitting diode. Since the semiconductor chip CHP1 and the semiconductor chip CHP2 are mounted in one package, the package PACT of the seventh embodiment can reduce its size. That is, the seventh embodiment can also provide the package PAC2 that achieves both the low power consumption and the reduction in size.

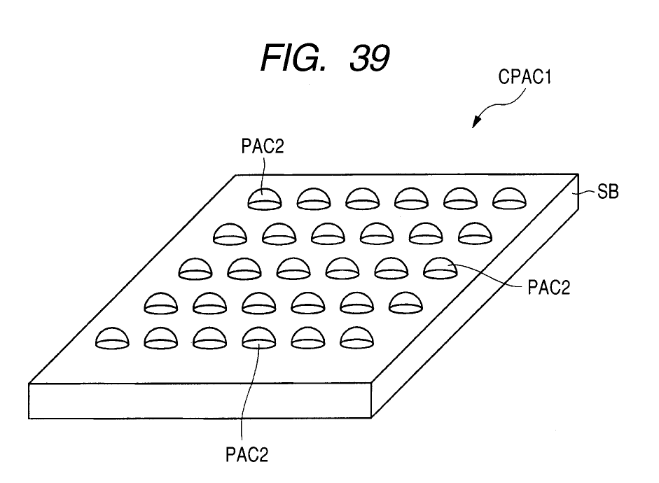

The following will describe a composite package (semiconductor device: moodule) CPAC1 including the above packages PAC2s coupled together in the form of a matrix. FIG. 39 is a perspective view showing the structure of the composite package CPAC1 in the seventh embodiment. As shown in FIG. 39, the packages PAC2s are arranged over the substrate SB in an array (or in the form of the matrix). In this way, the composite package (semiconductor device: moodule) CPAC1 can be formed. The composite package (semiconductor device: moodule) CPAC1 achieves the circuit shown in FIG. 4. Each package PAC2 in the thus-structured composite package (semiconductor device: moodule) CPAC1 achieves both the low power consumption and the reduction in size, so that the composite package (semiconductor device: moodule) CPAC1 including the packages PAC2 with such a feature arranged in the array can also achieve the low power consumption and the reduction in size.

### Eighth Embodiment

The seventh embodiment has described the package PAC1 or package PAC2 in which the semiconductor chip CHP1 with the light-emitting diode formed therein, and the semiconductor chip CHP2 with the bidirectional Zener diode or Zener diode formed therein are mounted together. In the packages PAC1 and PAC2, the semiconductor chip CHP2 is coupled to the wiring or lead via the wire W2. The wire W2 possibly makes a shadow of light emitted from the light-emitting diode, which may reduce the efficiency of irradiation with light from the packages PAC1 and PAC2. The eighth embodiment will describe the device structure in which the semiconductor chip CHP2 with the bidirectional Zener diode formed therein can be coupled not by the wire W2, but by a bump electrode. As shown in a tenth embodiment, the semiconductor chips CHP2 of this embodiment are included in the packages PAC1 or packages PAC2 constituting the composite package (semiconductor device: moodule) CPAC1, shown in the seventh embodiment and in FIG. 39.

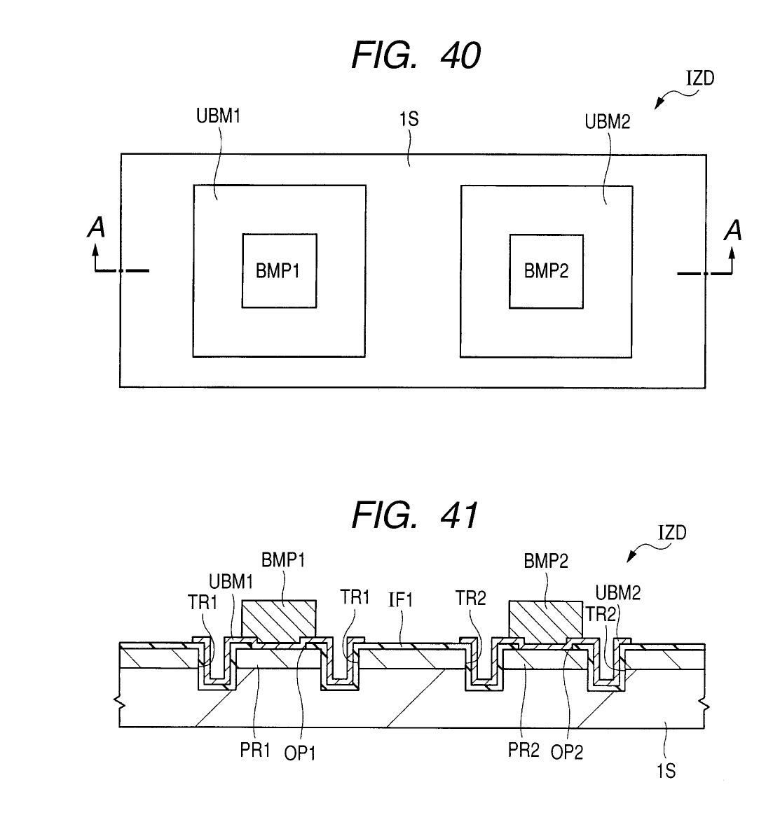

FIG. 40 is a plan view of the bidirectional Zener diode IZD of the eighth embodiment as viewed from the upper surface. Referring to FIG. 40, a rectangular under bump metal film UBM1 and a rectangular under bump metal film UBM2 are formed to be spaced apart from each other over the rectangular semiconductor substrate 1S. A bump electrode BMP1 is formed over the under bump metal film UBM1, and a bump electrode BMP2 is formed over the under bump metal film UBM2.

FIG. 41 is a cross-sectional view taken along the line A-A of FIG. 40. As shown in FIG. 41, a p-type semiconductor region is formed over an n-type semiconductor substrate 1S, and a trench TR1 (isolation region) and a trench TR2 (isolation region) are formed to reach the semiconductor substrate 1S from the surface of a p-type semiconductor region through the p-type semiconductor region. A first active region is isolated by a pair of trenches TR1s, and the p-type semiconductor region formed in the first active region isolated is a p-type semiconductor region PR1. That is, the p-type semiconductor region PR1 is formed by being interposed between the pair of trenches TRs. Similarly, a second active region is isolated by a pair of trenches TR2s, and the p-type semiconductor region formed in the second active region isolated is a p-type semiconductor region PR2. That is, the p-type semiconductor region PR2 is formed so as to be interposed between the pair of trenches TRs.

Subsequently, the protective insulating film IF1 is formed over the surface of the p-type semiconductor region so as to cover the p-type semiconductor region (p-type semiconductor region PR1 and p-type semiconductor region PR2), the pair of trenches TR1s, and the pair of trenches TR2s. The protective insulating film IF1 is comprised of, for example, a silicon oxide film, a silicon nitride film, a PSG film which is a glassy film provided by adding phosphorus into a silicon oxide film, or the like. At the protective insulating film IF1, an opening OP1 for exposing a part of the p-type semiconductor region PR1 is formed in the first active region, and an opening OP2 for exposing a part of the p-type semiconductor region PR2 is formed in the second active region.

In the first active region, an under bump metal film UBM1 is formed over the protective insulating film IF1 including the opening OP1, and a bump electrode BMP1 is formed over the under bump metal film UBM1. In the second active region, an under bump metal film UBM2 is formed over the protective insulating film IF1 including the inside of the opening OP2, and a bump electrode BMP2 is formed over the under bump metal film UBM2. The under bump metal films UBM1 and UBM2 are comprised of, for example, a titanium (Ti) film or a molybdenum (Mo) film. The bump electrodes BMP1 and BMP2 are comprised of, for example, a gold film.

The feature of the eighth embodiment is that the under bump metal film UBM1 extends from the inside of the opening OP1 to cover the inner walls of a pair of trenches TR1s, and that the under bump metal film UBM2 extends from the inside of the opening OP2 to cover the inner walls of a pair of trenches TR2s.

The under bump metal films UBM1 and UBM2 are formed of a conductive film containing metal, for example, a titanium film or a molybdenum film, and has the light blocking effect. That is, in the bidirectional Zener diode IZD of the eighth embodiment, the inner wall of the trench TR1 is covered with the under bump metal film UBM1 having the light blocking effect, and the inner wall of the trench TR2 is covered with the under bump metal film UBM2 having the light blocking effect. Even when the light is applied to the bidirectional Zener diode IZD, the light can be prevented from entering the p-n junction formed at the boundary between the p-type semiconductor region PR1 and the semiconductor substrate 1S from the inner wall of the trench TR. Likewise, the light can be prevented from entering the p-n junction formed at the boundary between the p-type semiconductor region PR2 and the semiconductor substrate 1S from the inner wall of the trench TR2. Thus, the occurrence of the photoelectric effect at the p-n junction can be prevented.

That is, the bidirectional Zener diode IZD of the eighth embodiment can reduce the leak current at the p-n junction due to the photoelectric effect. This means that the current passing through the light-emitting diode LED coupled in parallel to the bidirectional Zener diode IZD can be ensured to reduce the loss of current. Since the leak current at the bidirectional Zener diode IZD can be reduced, the Zener diode IZD can improve the efficiency of use of current for emission of light from the light-emitting diode LED to thereby reduce the useless current not contributing to the light emission of the light-emitting diode LED. In this way, the bidirectional Zener diode IZD of the eighth embodiment can reduce the leak current due to the photoelectric effect, and as a result, can improve the efficiency of use of current at the diode LED.

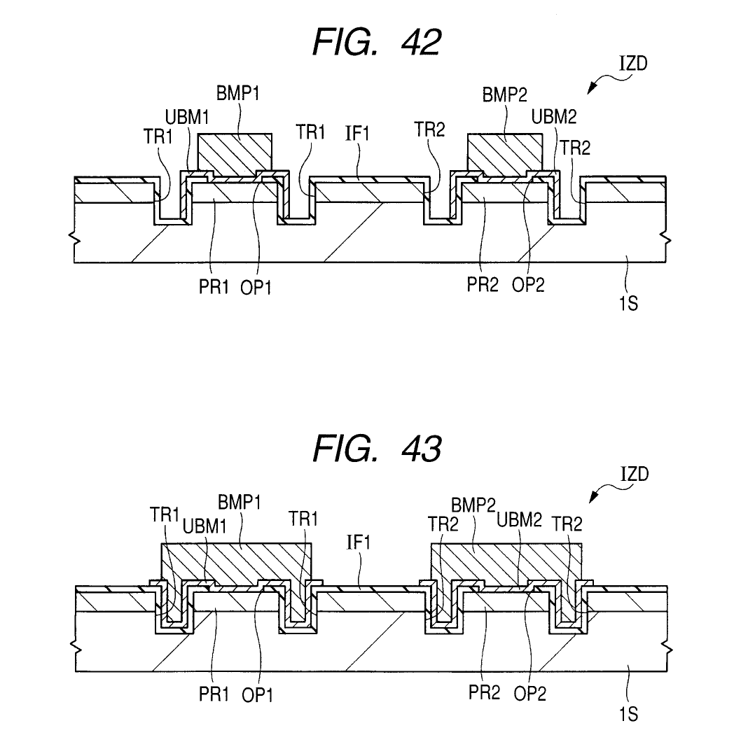

Now, a modified example of the bidirectional Zener diode IZD of the eighth embodiment will be described below. FIG. 42 is a cross-sectional view showing the structure of the bidirectional Zener diode IZD in the modified example. The bidirectional Zener diode IZD shown in FIG. 42 has substantially the same structure as that of the bidirectional Zener diode IZD shown in FIG. 41, and difference points therebetween will be described below. Specifically, in the bidirectional Zener diode IZD shown in FIG. 41, the under bump metal films UBM1 and UBM2 are formed to cover the inner walls of the trenches TR1 and TR2 (both sides thereof). In contrast, in the bidirectional Zener diode IZD shown in FIG. 42, the under bump metal film UBM1 is formed to extend from the inside of the opening OP1, and to cover at least one side of both sides of the trench TR1 (side surface on one side) in contact with the first active region having the bidirectional Zener diode IZD formed therein. Likewise, the under bump metal film. UBM2 is formed to extend from the inside of the opening OP2, and to cover at least one side of both sides of the trench TR2 (side surface on one side) in contact with the second active region having the bidirectional Zener diode IZD formed therein.

Such a structure can also prevent the light from entering the p-n junction formed at the boundary between the p-type semiconductor region PR1 and the semiconductor substrate 1S, and the p-n junction formed at the boundary between the p-type semiconductor region PR2 and the semiconductor substrate 1S, from the inner wall of the trench TR1 or the inner wall of the trench TR2. Thus, the occurrence of the photoelectric effect in the p-n junction can be suppressed. Unless the light is applied to the p-n junction within the first active region formed on the inner side of both sides of the trench TR1, the leak current due to the photoelectric effect can be reduced. Likewise, unless the light is applied to the p-n junction within the second active region formed on the inner side of both sides of the trench TR2, the leak current due to the photoelectric effect can be reduced.

From this point, in the bidirectional Zener diode IZD of the eighth embodiment, like the bidirectional Zener diode IZD shown in FIG. 42, the under bump metal film UBM1 may be formed so as to cover at least one side of both sides of the trench TR1 (side surface on one side) in contact with the first active region having the bidirectional Zener diode IZD formed therein. Likewise, the under bump metal film UBM2 may be formed so as to cover one side of both sides of the trench TR2 (side surface on one side) in contact with the second active region having the bidirectional Zener diode IZD formed therein.

Further, another modified example of the bidirectional Zener diode IZD of the eighth embodiment will be described below. FIG. 43 is a cross-sectional view showing the structure of the bidirectional Zener diode IZD in the modified example. The bidirectional Zener diode IZD shown in FIG. 43 has substantially the same structure as that of the bidirectional Zener diode IZD shown in FIG. 41, and different points therebetween will be described below. Specifically, in the bidirectional Zener diode IZD shown in FIG. 43, not only the under bump metal film UBM1, but also the bump electrode BMP1 formed over the under bump metal film UBM1 covers a pair of trenches TR1s. Likewise, in the bidirectional Zener diode IZD shown in FIG. 43, not only the under bump metal film UBM2, but also the bump electrode BMP2 formed over the under bump metal film UBM2 covers a pair of trenches TR2s.

This arrangement can surely prevent light from being applied to the inside of the trench TR1 or TR2. As a result, the bidirectional Zener diode IZD of the modified example can reduce the leak current due to the photoelectric effect.

The bidirectional Zener diode IZD of the eighth embodiment has the structure described above, and a manufacturing method thereof will be described below with reference to the accompanying drawings.

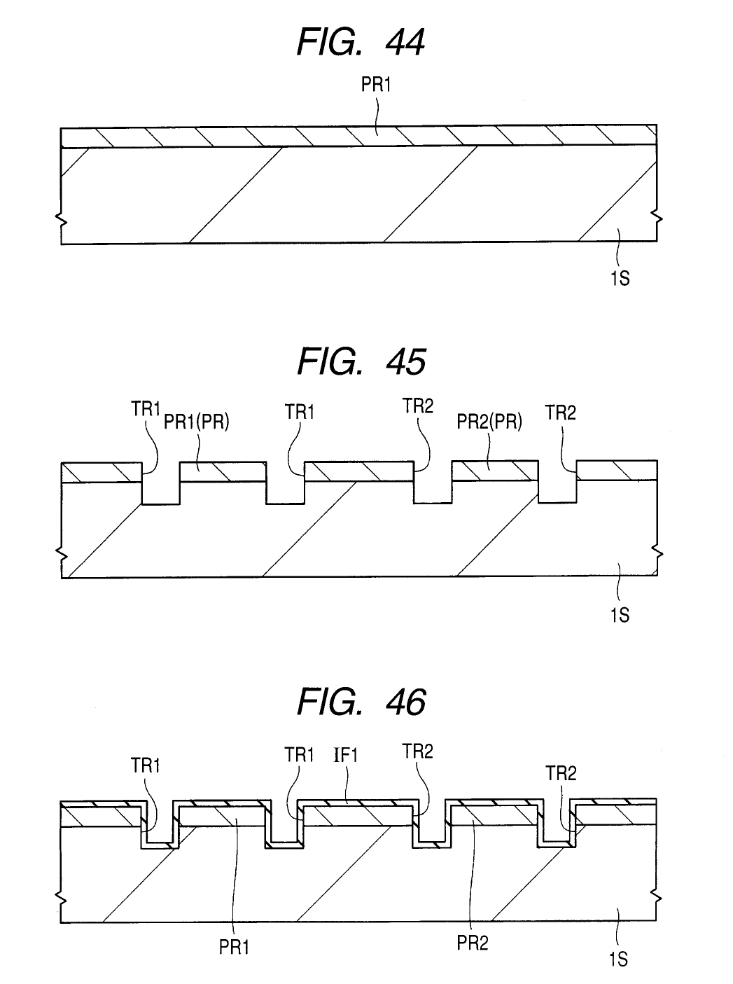

First, as shown in FIG. 44, n-impurities, such as phosphorus (P), are introduced into a semiconductor substrate as a conductive impurity to prepare an n-type semiconductor substrate 1S. Then, a p-type semiconductor region PR is formed over the n-type semiconductor substrate 1S. The p-type semiconductor region PR can be formed by using, for example, the ion implantation method or the epitaxial growth. The p-type semiconductor region PR has p-type impurities, such as boron (B), introduced thereinto as a conductive impurity.

Then, as shown in FIG. 45, a pair of trenches TR1s for isolating the first active region is formed to reach the inside of the semiconductor substrate 1S from the surface of the p-type semiconductor region PR, and a pair of trenches TR2s for isolating the second active region is formed to reach the inside of the semiconductor substrate 1S from the surface of the p-type semiconductor region PR. At this time, the p-type semiconductor region PR formed in the first active region interposed between the pair of trenches TR1s is the p-type semiconductor region PR1, and the p-type semiconductor region PR formed in the second active region interposed between the pair of trenches TR2s is the p-type semiconductor region PR2.

Subsequently, as shown in FIG. 46, the protective insulating film IF1 is formed over the p-type semiconductor region PR (including the p-type semiconductor region PR1 and p-type semiconductor region PR2), the inner walls of the pair of trenches TR1s, and the inner walls of the pair of trenches TR2s. The protective insulating film IF1 can be comprised of, for example, a silicon oxide film, a silicon nitride film, a PSG film which is a glassy film provided by adding phosphorus into a silicon oxide film, or the like.

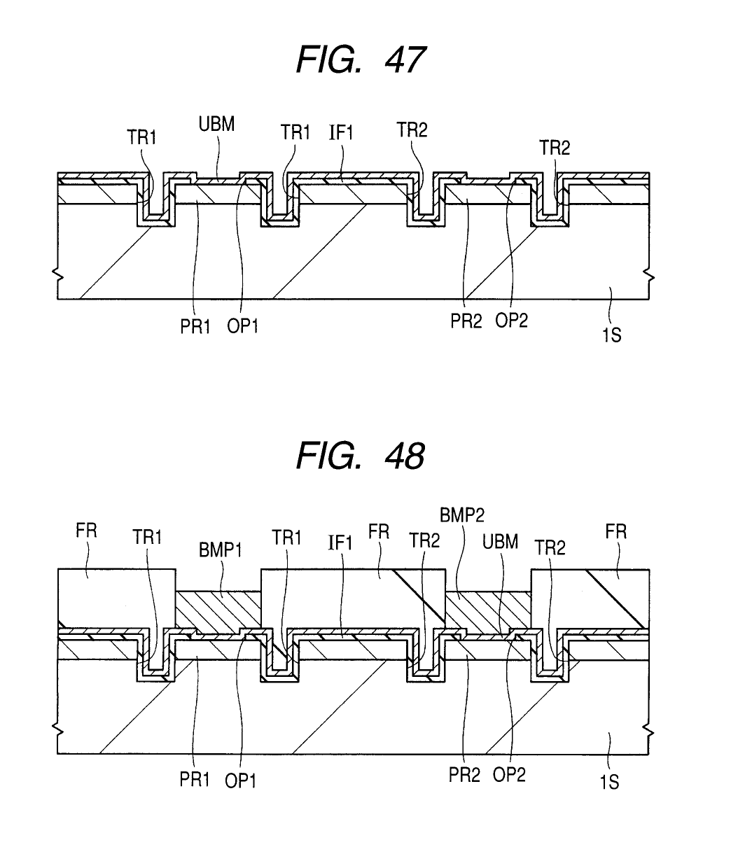

As shown in FIG. 47, the protective insulating film IF1 is processed by the photolithography technique and the etching technique to thereby form the opening OP1 in the protective insulating film IF1 formed in the first active region, and to form the opening OP2 in the protective insulating film IF1 formed in the second active region. Thus, a part of the p-type semiconductor region PR1 is exposed from the opening OP1, and a part of the p-type semiconductor region PR2 is exposed from the opening OP2.

Thereafter, the under bump metal film UBM is formed over the p-type semiconductor region PR1 exposed from the opening OP1, the p-type semiconductor region PR2 exposed from the opening OP2, and the protective insulating film IF1. The under bump metal film UBM can be comprised of, for example, a titanium film or a molybdenum film. The film UBM can be formed, for example, by sputtering. In this step, the under bump metal film UBM is formed to cover the inner wall of the trench TR1 and the inner wall of the trench TR2.

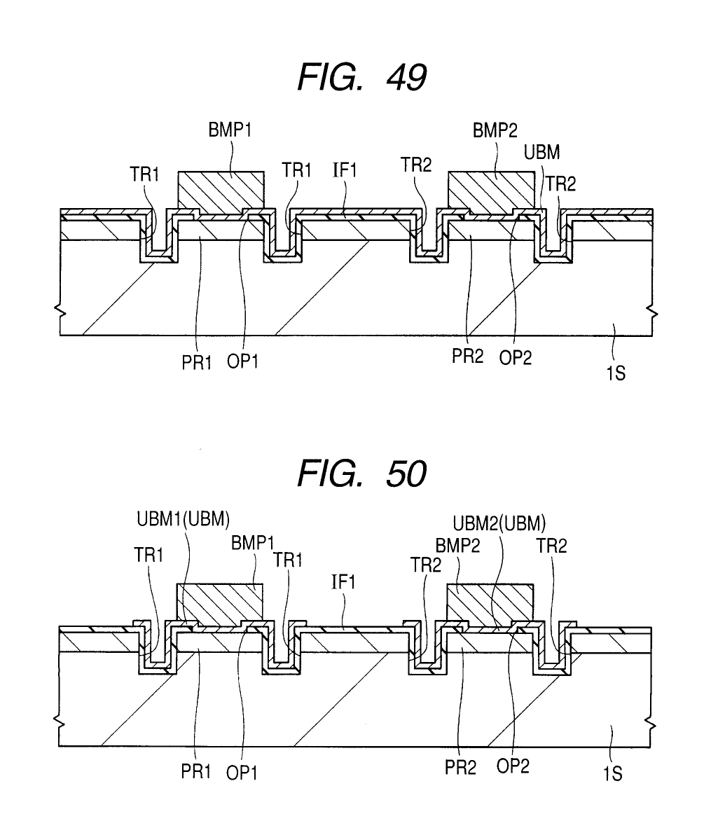

Then, as shown in FIG. 48, after forming a resist film FR over the under bump metal film UBM, the resist film FR is subjected to exposure and development processes to be patterned. The resist film FR is patterned so as to open a region for formation of a bump electrode. Specifically, the resist film FR is patterned so as to open a part of the film FR above the first active region interposed between the pair of trenches TR1s, and another part of the film FR above the first active region interposed between the pair of trenches TR2s. Then, a gold film is formed over the under bump metal film UBM exposed from the opening formed in the resist film FR by use of electrolytic plating to thereby form a bump electrode BMP1 and a bump electrode BMP2. Specifically, the bump electrode BMP1 is formed over the under bump metal film UBM in the first active region, and the bump electrode BMP2 is formed over the under bump metal film UBM in the second active region. Then, as shown in FIG. 49, the patterned resist film FR is removed.

Subsequently, as shown in FIG. 50, the bump metal film UBM exposed by removal of the resist film FR is processed. That is, the under bump metal film UBM formed in the first active region is separated from the under bump metal film UBM formed in the second active region, so that the under bump metal film UBM1 is formed in the first active region, and the under bump metal film UBM2 is formed in the second active region. In this step, the under bump metal film UBM1 is processed so as to extend from the inside of the opening OP1 and to cover the inner walls of the pair of trenches TR1s. The under bump metal film UBM2 is processed so as to extend from the inside of the opening OP2 and to cover the inner walls of the pair of trenches TR2s.

Then, the back side of the semiconductor substrate 1S is polished (back-ground) to make the semiconductor substrate 1S thinner.

In this way, the bidirectional Zener diode IZD of the eighth embodiment can be manufactured. In the bidirectional Zener diode IZD of the eighth embodiment, the inner wall of the trench TR1 is covered with the under bump metal film UBM1 (light blocking film) having the light blocking effect, and the inner wall of the trench TR2 is covered with the under bump metal film UBM2 (light blocking film) having the light blocking effect. Even when the light is applied to the bidirectional Zener diode IZD, the light can be prevented from entering the p-n junction from the inner wall of the trench TR. Thus, according to the eighth embodiment, the leak current due to the photoelectric effect can be reduced.

### Ninth Embodiment

A ninth embodiment of the invention will describe a device structure which can couple a semiconductor chip with a Zener diode formed to a bump electrode.

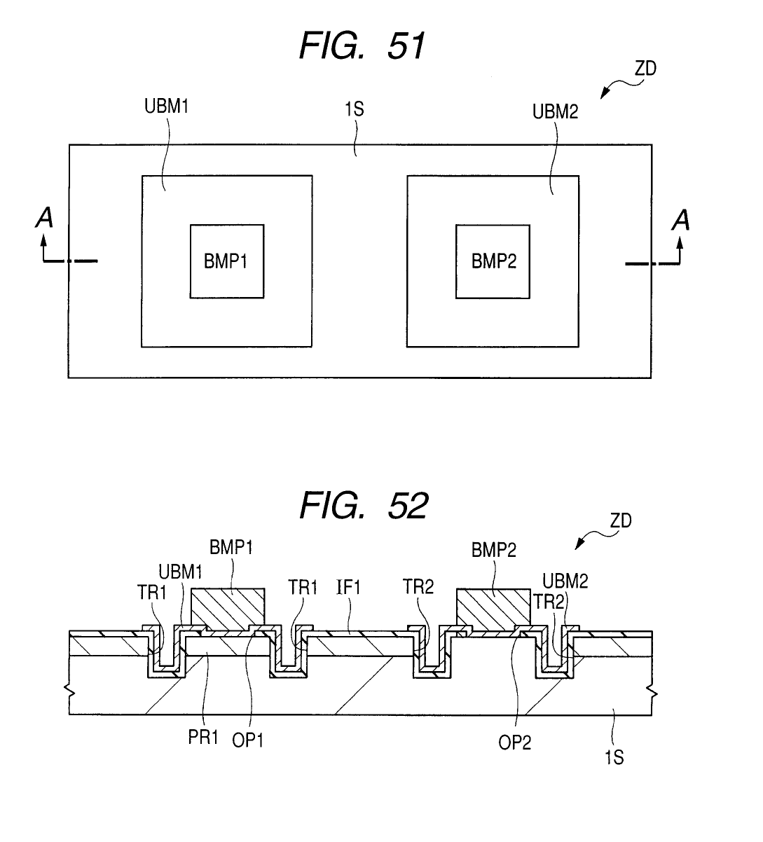

FIG. 51 is a plan view of the Zener diode ZD of the ninth embodiment as viewed from the upper surface. Referring to FIG. 51, a rectangular under bump metal film UBM1 and a rectangular under bump film UBM2 are formed to be spaced apart from each other over a rectangular semiconductor substrate 1S. A bump electrode BMP1 is formed over the under bump metal film UBM1, and a bump electrode BMP2 is formed over the under bump metal film UBM2.

FIG. 52 is a cross-sectional view taken along the line A-A of FIG. 51. As shown in FIG. 52, a p-type semiconductor region is formed over the n-type semiconductor substrate 1S, and a trench TR1 (isolation region) and a trench TR2 (isolation region) are formed to reach the semiconductor substrate 1S from the p-type semiconductor region through the p-type semiconductor region. The first active region is isolated by the pair of the trenches TR1s, and the p-type semiconductor region formed in the isolated first active region is a p-type semiconductor region PR1. That is, the p-type semiconductor region PR1 is formed to be interposed between the pair of trenches TRs. In contrast, the second active region is isolated by the pair of trenches TR2s, and the p-type semiconductor region is not formed in the second active region isolated.

Subsequently, a protective insulating film IF1 is formed over the surface of the p-type semiconductor region and the semiconductor substrate 1S to cover the semiconductor substrate 1S, the p-type semiconductor region (including the p-type semiconductor region PR1), the pair of trenches TR1s, and the pair of trenches TR2s. The protective insulating film IF1 is comprised of, for example, a silicon oxide film, a silicon nitride film, a PSG film which is a glassy film provided by adding phosphorus into a silicon oxide film, or the like. At the protective insulating film IF1, an opening OP1 for exposing a part of the p-type semiconductor region PR1 is formed in the first active region, and an opening OP2 for exposing a part of the semiconductor substrate 1S is formed in the second active region.

In the first active region, an under bump metal film UBM1 is formed over the protective insulating film IF1 including the opening OP1, and a bump electrode BMP1 is formed over the under bump metal film UBM1. In the second active region, an under bump metal film UBM2 is formed over the protective insulating film IF1 including the inside of the opening OP2, and a bump electrode BMP2 is formed over the under bump metal film UBM2. The under bump metal films UBM1 and UBM2 are comprised of, for example, a titanium (Ti) film or a molybdenum (Mo) film. The bump electrodes BMP1 and BMP2 are formed of, for example, a gold film.

The feature of the ninth embodiment is that the under bump metal film UBM1 is formed to extend from the inside of the opening OP1 and to cover the inner walls of a pair of trenches TR1s, and that the under bump metal film UBM2 is formed to extend from the inside of the opening OP2 and to cover the inner walls of a pair of trenches TR2s.

The under bump metal films UBM1 and UBM2 are comprised of a conductive film containing metal, for example, a titanium film or a molybdenum film, and has the light blocking effect. That is, in the Zener diode ZD of the ninth embodiment, the inner wall of the trench TR1 is covered with the under bump metal film UBM1 having the light blocking effect, and the inner wall of the trench TR2 is covered with the under bump metal film UBM2 having the light blocking effect. Even when the light is applied to the Zener diode ZD, the light can be prevented from entering the p-n junction formed at the boundary between the p-type semiconductor region PR1 and the semiconductor substrate 1S from the inner wall of the trench TR1. Thus, the occurrence of the photoelectric effect in the p-n junction can be suppressed.

That is, the Zener diode ZD of the ninth embodiment can reduce the leak current due to the photoelectric effect in the p-n junction. This means that the current passing through the light-emitting diode LED coupled in parallel to the Zener diode IZD can be ensured to thereby reduce the loss of current. Since the leak current at the Zener diode ZD can be reduced, the Zener diode IZD can improve the efficiency of use of current for emission of light from the light-emitting diode LED to thereby reduce the useless current not contributing to the light emission of the light-emitting diode LED. In this way, the Zener diode ZD of the ninth embodiment can reduce the leak current due to the photoelectric effect, and as a result, can improve the efficiency of use of current at the diode LED.

The inner wall of the trench TR2 may not be covered with the under bump metal film UBM2 having the light blocking effect. This is because only the semiconductor substrate 1S exists in the second active region, in which the p-n junction is not formed.

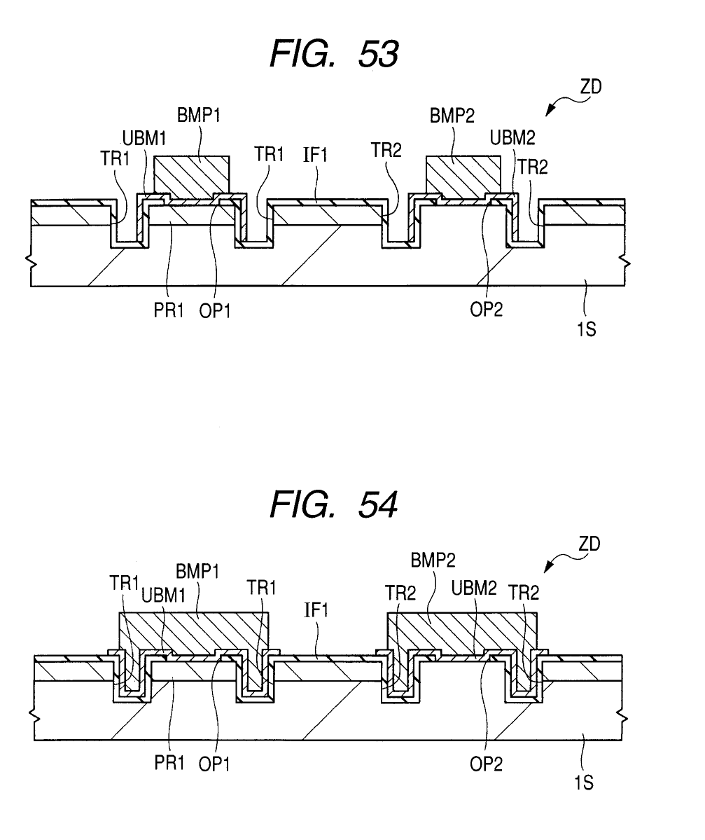

Next, a modified example of the Zener diode ZD of the ninth embodiment will be described below. FIG. 53 is a cross-sectional view showing the structure of the Zener diode ZD in the modified example. The Zener diode ZD shown in FIG. 53 has substantially the same structure as that of the Zener diode ZD shown in FIG. 52, and different points therebetween will be described below. Specifically, the Zener diode ZD shown in FIG. 52 has the under bump metal film UBM1 and the under bump metal film UBM2 formed so as to cover the inner walls (both sides) of the trenches TR1 and TR2. In contrast, in the Zener diode ZD shown in FIG. 53, the under bump metal film UBM1 is formed to extend from the inside of the opening OP1, and to cover at least one side of both sides of the trench TR1 (side surface on one side) in contact with the first active region having the Zener diode ZD formed therein. Likewise, the under bump metal film UBM2 is formed to extend from the inside of the opening OP2, and to cover at least one side of both sides of the trench TR2 (side surface on one side) in contact with the second active region having the Zener diode ZD formed therein.

Also, with this arrangement, light can be prevented from entering the p-n junction formed at the boundary between the semiconductor substrate 1S and the p-type semiconductor region PR1 from the inner wall of the trench TR1. Thus, the occurrence of the photoelectric effect can be suppressed in the p-n junction. When the light is not applied to the p-n junction positioned in the first active region formed on the inner one of both sides of the trench TR1, the leak current due to the photoelectric effect can be reduced.

From this point, in the Zener diode ZD of the ninth embodiment, like the Zener diode ZD shown in FIG. 53, the under bump metal film UBM1 may be formed to cover at least one side of both sides of the trench TR1 (side surface on one side) in contact with the first active region having the Zener diode ZD formed therein.

Further, another modified example of the Zener diode ZD of the ninth embodiment will be described below. FIG. 54 is a cross-sectional view showing the structure of the Zener diode ZD in the modified example. The Zener diode ZD shown in FIG. 54 has substantially the same structure as that of the Zener diode ZD shown in FIG. 52, and different points therebetween will be described below. Specifically, in the Zener diode ZD shown in FIG. 54, not only the under bump metal film UBM1, but also the bump electrode BMP1 formed over the under bump metal film UBM1 is formed so as to cover the pair of trenches TR1s. Likewise, in the Zener diode ZD shown in FIG. 54, not only the under bump metal film UBM2, but also the bump electrode BMP2 formed over the under bump metal film UBM2 is formed so as to cover the pair of trenches TR2s.

This can surely prevent the light from being applied to the insides of the trench TR1 and the trench TR2. As a result, the Zener diode ZD in the modified example can reduce the leak current due to the photoelectric effect.

The Zener diode ZD of the ninth embodiment has the structure described above, and a manufacturing method thereof is substantially the same as that of the eighth embodiment. Specifically, in the ninth embodiment, the p-type semiconductor region PR is not formed over the entire main surface of the semiconductor substrate 1S, unlike the embodiment shown in FIG. 44. That is, in the ninth embodiment, the p-type semiconductor region PR is selectively formed in the first active region of the semiconductor substrate 1S, and not in the second active region of the semiconductor substrate 1S. The following steps are substantially the same as those of the eighth embodiment except that the p-type semiconductor region PR is not formed in the second active region. As mentioned above, the Zener diode ZD of the ninth embodiment can be manufactured. As shown in a tenth embodiment, the Zener diodes ZD of the ninth embodiment are included in the packages PACT or packages PAC2 constituting the composite package (semiconductor device: moodule) CPAC1, shown in the seventh embodiment and in FIG. 39.

### Tenth Embodiment

The eighth embodiment has described the device structure of the bidirectional Zener diode with the bump electrodes formed therein, and the ninth embodiment has described the device structure of the Zener diode with the bump electrodes formed therein. The tenth embodiment has described a package structure including the bidirectional Zener diode described in the eighth embodiment and the light-emitting diode which are mounted in one package, or a package structure including the Zener diode described in the ninth embodiment and the light-emitting diode which are mounted in one package.

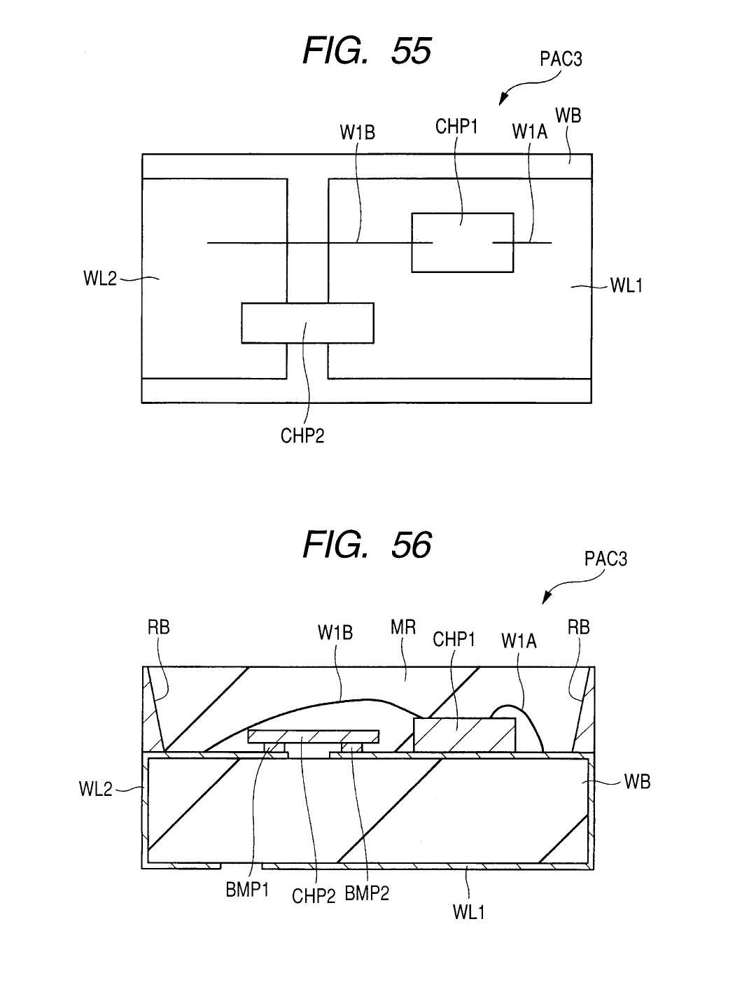

FIG. 55 is a plan view showing a semiconductor device (package structure) of the tenth embodiment. As shown in FIG. 55, a package PAC3 (semiconductor device) of the tenth embodiment includes a rectangular wiring board WB, over which a wiring WL1 and a wiring WL2 are formed. The wiring WL1 and the wiring WL2 are electrically separated from each other. A semiconductor chip CHP1 is mounted over the wiring WL1, and coupled to the wiring WL1 via a wire W1A. The semiconductor chip CHP1 is coupled to the wiring WL2 via a wire W1B. The semiconductor chip CHP1 has a light-emitting diode formed therein. In contrast, the semiconductor chip CHP2 is mounted to extend over the wiring WL1 and the wiring WL2. The semiconductor chip CHP2 has the bidirectional Zener diode or Zener diode formed therein.

FIG. 56 is a cross-sectional view showing one section of the package PAC3 shown in FIG. 55. Referring to FIG. 56, the wiring WL1 and the wiring WL2 are formed at the wiring board WB, the semiconductor chip CHP1 is mounted over the wiring WL1, and the semiconductor chip CHP2 is mounted to extend over the wiring WL1 and the wiring WL2. The semiconductor chip CHP1 is coupled to the wiring WL1 via the wire W1A, and to the wiring WL2 via the wire W1B. In contrast, the semiconductor chip CHP2 is coupled to the wiring WL2 via the bump electrode BMP1, and to the wiring WL1 via the bump electrode BMP2. At this time, a light-emitting diode is formed in the semiconductor chip CHP1, and a bidirectional Zener diode or a Zener diode is formed in the semiconductor chip CHP2. Reflective boards RBs are formed above the wiring board WB, and the semiconductor chip CHP1 and the semiconductor chip CHP2 are sealed with resin MR containing fluorescent material.

The circuit shown in each of FIGS. 1 and 3 is formed by the thus-structured package PAC3. When current passes through between the wirings WL1 and WL2 in the package PAC3, the current is allowed to flow through the light-emitting diode formed in the semiconductor chip CHP1, causing the diode to emit light. For example, the light-emitting diode formed in the semiconductor chip CHP1 is a blue light-emitting diode, and emits blue light. The blue light emitted from the light-emitting diode is converted into white light by being applied to the fluorescent material contained in the resin MR. In this way, the white light can be applied from the package PAC3. At this time, since the package PAC3 is provided with the reflective board RB, the blue light emitted from the light-emitting diode is effectively converted into the white light.

For example, suppose that the surge voltage is applied to the light-emitting diode from the outside. In this case, the surge voltage is also applied to the bidirectional Zener diode (simply, the Zener diode) coupled in anti-parallel to the light-emitting diode. Thus, when the surge voltage exceeds the breakdown voltage of the bidirectional Zener diode (Zener diode), the breakdown of the bidirectional Zener diode (Zener diode) occurs to absorb the surge voltage, which is converted into a small Zener voltage. As a result, the only small Zener voltage is applied to the light-emitting diode, which can protect the light-emitting diode from the surge voltage.

The semiconductor chip CHP2 used in the tenth embodiment is provided with the bidirectional Zener diode of the eighth embodiment, or the Zener diode of the ninth embodiment. Thus, even when the semiconductor chip CHP2 is mounted together with the semiconductor chip CHP1 in one package, the leak current due to the photoelectric effect can be reduced in the semiconductor chip CHP2. This means that the current passing through the light-emitting diode formed in the semiconductor chip CHP1 can be ensured to reduce the loss of current. Since the leak current due to the photoelectric effect in the semiconductor chip CHP2 can be reduced, the light-emitting diode can improve the efficiency of use of current for emission of light from the diode formed in the semiconductor chip CHP1 to thereby reduce the useless current not contributing to the light emission of the light-emitting diode. Since the semiconductor chip CHP1 and the semiconductor chip CHP2 are mounted in one package, the package PAC3 of the tenth embodiment can reduce its size. That is, the tenth embodiment can provide the package PAC3 that achieves both the low power consumption and the reduction in size.

Further, the feature of the package PAC3 of the tenth embodiment is that the semiconductor chip CHP2 with the bidirectional Zener diode or Zener diode formed therein is coupled to the wiring WL2 via the bump electrode BMP1, and to the wiring WL1 via the bump electrode BMP2. That is, in the package PAC3 of the tenth embodiment, the semiconductor chip CHP2 is coupled to the wiring (wiring WL1 and wiring WL2) via the bump electrodes (bump electrode BMP1 and bump electrode BMP2) and not via the wire. Thus, since there is no wire that makes a shadow of light generated from the light-emitting diode, the efficiency of irradiation with the light from the package PAC3 can be improved. The packages PAC3 are included in the composite package (semiconductor device: moodule) CPAC1, shown in the seventh embodiment and in FIG. 39.

Although the invention made by the inventors has been specifically described based on the embodiments, the invention is not limited to the embodiments disclosed therein. It is apparent that various modifications can be made without departing from the scope and spirit of the invention.

The invention can be applied to a case where a conduction type of the bidirectional Zener diode or Zener diode described in the above embodiments is reversed. Specifically, the invention can also be applied to another device structure (a package structure, module) in which the p-type semiconductor region of the diode described in the above embodiment is changed to an n-type semiconductor region, and the n-type semiconductor region is changed to a p-type semiconductor region.

The invention can be widely used to manufacturing industries for manufacturing semiconductor devices. The invention can be widely used to an apparatus including a diode affected by the photoelectric effect. The apparatus includes a display device, such as the LED display, for example.

What is claimed is:

1. A semiconductor device, comprising a bidirectional Zener diode formed in a first semiconductor chip, said bidirectional Zener diode comprising:
(a) a semiconductor substrate of a first conductive type;
(b) a first semiconductor region formed over the semiconductor substrate, said first semiconductor region being a second conductive type opposite to the first conductive type;
(c) a second semiconductor region formed over the first semiconductor region, said second semiconductor region being the first conductive type;
(d) an isolation region formed in a predetermined depth from a surface of the second semiconductor region;
(e) a protective insulating film formed over the surface of the second semiconductor region so as to cover the second semiconductor region and the isolation region, said protective insulating film having an opening for exposing a part of the second semiconductor region;
(f) a light blocking film formed over the protective insulating film including an inside of the opening; and
(g) a back electrode formed at a back surface of the semiconductor substrate,
wherein the light blocking film extends from the inside of the opening to cover the isolation region.

2. The semiconductor device according to claim 1, wherein the light blocking film is comprised of a conductive film containing metal.

3. The semiconductor device according to claim 2, wherein the light blocking film is an upper electrode of the bidirectional Zener diode.

4. The semiconductor device according to claim 1,
wherein the isolation region comprises a trench reaching an inside of the semiconductor substrate from a surface of the second semiconductor region through the second semiconductor region and the first semiconductor region,
wherein the protective insulating film is formed over the inner wall of the trench, and
wherein the light blocking film is formed to cover the trench via the protective insulating film formed over the inner wall of the trench.

5. The semiconductor device according to claim 1,
wherein the isolation region comprises a trench reaching an inside of the semiconductor substrate from the surface of the second semiconductor region through the second semiconductor region and the first semiconductor region, and a filling film for filling the trench, and
wherein the protective insulating film is formed over the filling film embedded in the trench.

6. The semiconductor device according to claim 5, wherein the filling film comprises a first insulating film formed at an inner wall of the trench, and a polysilicon film filling the trench via the first insulating film.

7. The semiconductor device according to claim 5, wherein the filling film comprises a second insulating film.

8. The semiconductor device according to claim 1,
wherein the isolation region comprises a third semiconductor region of the second conductive type formed to reach the first semiconductor region from the surface of the second semiconductor region, and
wherein a concentration of impurities in the third semiconductor region is higher than that in the first semiconductor region.

9. The semiconductor device according to claim 1, wherein the light blocking film is not formed over an area in a predetermined distance from an end of the semiconductor substrate.

10. The semiconductor device according to claim 1, further comprising a second semiconductor chip with a LED formed therein,
wherein the first semiconductor chip and the second semiconductor chip are mounted in one package.

11. The semiconductor device according to claim 10, wherein the package comprises a wiring board, the first semiconductor chip and the second semiconductor chip mounted over the wiring board, and a sealing resin for sealing the first semiconductor chip and the second semiconductor chip, said sealing resin containing fluorescent material.

12. A semiconductor device, comprising a bidirectional Zener diode formed in a first semiconductor chip, said bidirectional Zener diode comprising:
(a) a semiconductor substrate of a first conductive type;
(b) a first semiconductor region formed over the semiconductor substrate, said first semiconductor region being a second conductive type opposite to the first conductive type;
(c) a second semiconductor region formed over the first semiconductor region, said second semiconductor region being the first conductive type;
(d) a trench reaching an inside of the semiconductor substrate from a surface of the second semiconductor region through the second semiconductor region and the first semiconductor region;
(e) a protective insulating film formed over the surface of the second semiconductor region so as to cover the second semiconductor region and an inner wall of the trench, said protective insulating film having an opening for exposing a part of the second semiconductor region;
(f) a light blocking film formed over the protective insulating film including the opening; and
(g) a back electrode formed at a back surface of the semiconductor substrate,
wherein the light blocking film is formed to extend from an inside of the opening and to cover at least one side of both sides of the trench in contact with an active region having the bidirectional Zener diode formed therein.

13. A semiconductor device, comprising a bidirectional Zener diode formed in a first semiconductor chip, said bidirectional Zener diode comprising:
(a) a semiconductor substrate of a first conductive type;
(b) a first semiconductor region formed over the semiconductor substrate, said first semiconductor region being a second conductive type opposite to the first conductive type;
(c) a pair of first isolation regions each of which is formed in a predetermined depth from a surface of the first semiconductor region to isolate a first active region;
(d) a pair of second isolation regions each of which is formed in a predetermined depth from a surface of the first semiconductor region to isolate a second active region;
(e) a protective insulating film formed over the surface of the first semiconductor region so as to cover the first semiconductor region, the pair of the first isolation regions, and the pair of the second isolation regions, said protective insulating film having a first opening formed in the first active region for exposing a part of the first semiconductor region, and a second opening formed in the second active region for exposing a part of the first semiconductor region;
(f) a first under bump metal film formed over the protective insulating film including an inside of the first opening in the first active region;
(g) a first bump electrode formed over the first under bump metal film;
(h) a second under bump metal film formed over the protective insulating film including an inside of the second opening in the second active region; and
(i) a second bump electrode formed over the second under bump metal film,
wherein the first under bump metal film is formed to extend from the inside of the first opening and to cover the pair of the first isolation regions, and the second under bump metal film is formed to extend from the inside of the second opening and to cover the pair of the second isolation regions.

14. The semiconductor device according to claim 13,
wherein the pair of the first isolation regions comprises a pair of first trenches reaching the inside of the first semiconductor region from the surface of the first semiconductor region through the first semiconductor region,
wherein the pair of the second isolation regions comprises a pair of second trenches reaching the inside of the semiconductor substrate from the surface of the first semiconductor region through the first semiconductor region,
wherein the protective insulating film is formed over the inner walls of the pair of the first trenches and over the inner walls of the pair of the second trenches,
wherein the first under bump metal film is formed to extend from the inside of the first opening and to cover the inner walls of the pair of the first trenches, and
wherein the second under bump metal film is formed to extend from the inside of the second opening and to cover the inner walls of the pair of the second trenches.

15. The semiconductor device according to claim 14, wherein the first bump electrode is formed to cover the pair of the first trenches, and the second bump electrode is formed to cover the pair of the second trenches.

16. A semiconductor device, comprising a Zener diode formed in a first semiconductor chip, said Zener diode comprising:
(a) a semiconductor substrate of a first conductive type;
(b) a first semiconductor region formed over the semiconductor substrate, said first semiconductor region being a second conductive type opposite to the first conductive type;
(c) an isolation region formed in a predetermined depth from a surface of the first semiconductor region;
(d) a protective insulating film formed over the surface of the first semiconductor region so as to cover the first semiconductor region and the isolation region, said protective insulating film having an opening for exposing apart of the first semiconductor region;
(e) a light blocking film formed over the protective insulating film including an inside of the opening; and
(f) a back electrode formed at a back surface of the semiconductor substrate,
wherein the light blocking film extends from the inside of the opening to cover the isolation region.

17. The semiconductor device according to claim 16, wherein the light blocking film comprises a conductive film containing metal.

18. The semiconductor device according to claim 17, wherein the light blocking film is an upper electrode of the Zener diode.

19. The semiconductor device according to claim 16,
wherein the isolation region comprises a trench reaching an inside of the semiconductor substrate from a surface of the first semiconductor region through the first semiconductor region,
wherein the protective insulating film is formed over the inner wall of the trench, and
wherein the light blocking film is formed to cover the trench via the protective insulating film formed over the inner wall of the trench.

20. The semiconductor device according to claim 16,
wherein the isolation region comprises a trench reaching an inside of the semiconductor substrate from a surface of the first semiconductor region through the first semiconductor region, and a filling film for filling the trench, and
wherein the protective insulating film is formed over the filling film embedded in the trench.

21. The semiconductor device according to claim 20, wherein the filling film comprises a first insulating film formed at an inner wall of the trench, and a polysilicon film filling the trench via the first insulating film.

22. The semiconductor device according to claim 20, wherein the filling film comprises a second insulating film.

23. The semiconductor device according to claim 16,
wherein the isolation region comprises a third semiconductor region of the first conductive type formed to reach the semiconductor substrate from the surface of the first semiconductor region, and
wherein a concentration of impurities in the third semiconductor region is higher than that in the semiconductor substrate.

24. The semiconductor device according to claim 16, wherein the light blocking film is not formed over an area in a predetermined distance from an end of the semiconductor substrate.

25. The semiconductor device according to claim 16, further comprising a second semiconductor chip with a LED formed therein,
wherein the first semiconductor chip and the second semiconductor chip are mounted in one package.

26. The semiconductor device according to claim 25, wherein the package comprises a wiring board, the first semiconductor chip and the second semiconductor chip mounted over the wiring board, and a sealing resin for sealing the first semiconductor chip and the second semiconductor chip, and containing fluorescent material.

27. A semiconductor device, comprising a Zener diode formed in a first semiconductor chip, said Zener diode comprising:
(a) a semiconductor substrate of a first conductive type;
(b) a first semiconductor region formed over the semiconductor substrate, said first semiconductor region being a second conductive type opposite to the first conductive type;
(c) a trench reaching an inside of the semiconductor substrate from a surface of the first semiconductor region through the first semiconductor region;
(d) a protective insulating film formed over the surface of the first semiconductor region to cover the first semiconductor region and the inner wall of the trench, said protective insulating film having an opening formed for exposing a part of the first semiconductor region;
(e) a light blocking film formed over the protective insulating film including the inside of the opening; and
(f) a back electrode formed at a back surface of the semiconductor device,
wherein the light blocking film is formed to extend from the inside of the opening and to cover at least one side of both sides of the trench in contact with the active region having the Zener diode formed therein.

28. A semiconductor device, comprising a Zener diode formed in a first semiconductor chip, said Zener diode comprising:
(a) a semiconductor substrate of a first conductive type;
(b) a first semiconductor region formed in a first active region of the semiconductor substrate and not in a second active region of the semiconductor substrate, said first semiconductor substrate being a second conductive type opposite to the first conductive type;
(c) a pair of first isolation regions each of which is formed in a predetermined depth from a surface of the first semiconductor region to isolate the first active region;
(d) a pair of second isolation regions each of which is formed in a predetermined depth from a surface of the semiconductor substrate to isolate the second active region;
(e) a protective insulating film formed over the surface of the first semiconductor region and the surface of the semiconductor substrate so as to cover the pair of the first isolation regions and the pair of the second isolation regions, said protective insulating film having a first opening formed in the first active region for exposing a part of the first semiconductor region, and a second opening formed in the second active region for exposing a part of the semiconductor substrate;
(f) a first under bump metal film formed over the protective insulating film including the first opening in the first active region;
(g) a first bump electrode formed over the first under bump metal film;
(h) a second under bump metal film formed over the protective insulating film including the second opening in the second active region; and
(i) a second bump electrode formed over the second under bump metal film,
wherein the first under bump metal film is formed to extend from an inside of the first opening and to cover the pair of the first isolation regions.

29. The semiconductor device according to claim 28,
wherein the pair of the first isolation regions comprises a pair of first trenches reaching the inside of the first semiconductor region from the surface of the first semiconductor region through the first semiconductor region,
wherein the pair of the second isolation regions comprises a pair of second trenches reaching the inside of the semiconductor substrate from the surface of the first semiconductor region through the first semiconductor region,
wherein the protective insulating film is also formed over the inner walls of the pair of the first trenches and the inner walls of the pair of the second trenches, and
wherein the first under bump metal film is formed to extend from the inside of the first opening and to cover the inner walls of the pair of the first trenches.

30. The semiconductor device according to claim 29, wherein the first bump electrode is formed to cover the pair of the first trenches.

31. A method of manufacturing a semiconductor device, comprising the steps of:
(a) preparing a semiconductor substrate of a first conductive type;
(b) forming a first semiconductor region of a second conductive type opposite to the first conductive type over the semiconductor substrate;
(c) forming a second semiconductor region of the first conductive type in an area from an inside to a surface of the first semiconductor region;
(d) forming an isolation region reaching in a predetermined depth from the surface of the second semiconductor region to isolate an active region;
(e) forming a protective insulating film over the second semiconductor region and the isolation region;
(f) forming an opening in the protective insulating film formed in the active region by processing the protective insulating film to expose the second semiconductor region from the opening;
(g) forming a light blocking film over an area from the second semiconductor region exposed from the opening up to the protective insulating film; and
(h) processing the light blocking film,
wherein in the step (h), the light blocking film is processed so as to extend from an inside of the opening to cover the isolation region.

32. The method of manufacturing a semiconductor device according to claim 31,
wherein the step (d) comprises a step of forming a trench reaching the inside of the semiconductor substrate from the surface of the second semiconductor region through the second semiconductor region and the first semiconductor region;
wherein in the step (e), the protective insulating film is also formed over an inner wall of the trench, and
wherein in the step (h), the light blocking film is processed so as to cover the inner wall of the trench via the protective insulating film formed over the inner wall of the trench.

33. The method of manufacturing a semiconductor device according to claim 32,
wherein the step (d) comprises steps of forming a trench reaching the inside of the semiconductor substrate from the surface of the second semiconductor region through the second semiconductor region and the first semiconductor region, and embedding a filling film in the trench, and
wherein in the step (e), the protective insulating film is formed over the filling film embedded in the trench.

34. The method of manufacturing a semiconductor device according to claim 31,
wherein the step (d) comprises a step of forming a third semiconductor region of the second conductive type such that the third semiconductor region reaches the first semiconductor region from the surface of the second semiconductor region,
wherein a concentration of impurities in the third semiconductor region is higher than that in the first semiconductor region.

35. A method of manufacturing a semiconductor device, comprising the steps of:
(a) preparing a semiconductor substrate of a first conductive type;
(b) forming a first semiconductor region of a second conductive type opposite to the first conductive type over the semiconductor substrate;
(c) forming a pair of first trenches reaching the inside of the semiconductor substrate from the surface of the first semiconductor region to isolate a first active region, and forming a pair of second trenches reaching the inside of the semiconductor substrate from the surface of the first semiconductor region to isolate a second active region;
(d) forming a protective insulating film over the second semiconductor region, the inner walls of the pair of the first trenches, and the inner walls of the pair of the second trenches;
(e) forming a first opening in the protective insulating film formed in the first active region and a second opening in the protective insulating film formed in the second active region by processing the protective insulating film;
(f) forming an under bump metal film over the second semiconductor region exposed from the first opening, the second semiconductor region exposed from the second opening, and the protective insulating film;
(g) forming a first bump electrode over the under bump metal film formed in the first active region, and a second bump electrode over the under bump metal film formed in the second active region; and
(h) separating the under bump metal film formed in the first active region from the under bump metal film formed in the second active region to thereby form a first under bump metal film in the first active region and a second under bump metal film in the second active region,
wherein in the step (h), the first under bump metal film is processed so as to extend from an inside of the first opening and to cover inner walls of the pair of the first trenches, and the second under bump metal film is processed so as to extend from an inside of the second opening and to cover inner walls of the pair of the second trenches.

36. A method of manufacturing a semiconductor device, comprising the steps of:
(a) preparing a semiconductor substrate of a first conductive type;
(b) forming a first semiconductor region of a second conductive type opposite to the first conductive type over the semiconductor substrate;
(c) forming an isolation region reaching from a surface of the first semiconductor region to an inside of the semiconductor substrate to isolate an active region;
(d) forming a protective insulating film over the first semiconductor region and the isolation region;
(e) forming an opening in the protective insulating film formed in the active region by processing the protective insulating film to expose the first semiconductor region from the opening;
(f) forming a light blocking film over the protective insulating film from the first semiconductor region exposed from the opening; and
(g) processing the light blocking film,
wherein in the step (g), the light blocking film is processed so as to extend from the inside of the opening to cover the isolation region.

37. The method of manufacturing a semiconductor device according to claim 36,
wherein the step (c) comprises a step of forming a trench reaching an inside of the semiconductor substrate from a surface of the first semiconductor region through the first semiconductor region;
wherein in the step (d), the protective insulating film is also formed over the inner wall of the trench, and
wherein in the step (g), the light blocking film is processed so as to cover the inner wall of the trench via the protective insulating film formed over the inner wall of the trench.

38. The manufacturing method of a semiconductor device according to claim 37,
wherein the step (c) comprises steps of forming a trench reaching the inside of the semiconductor substrate from the surface of the first semiconductor region through the first semiconductor region, and embedding a filling film in the trench, and
wherein in the step (d), the protective insulating film is formed over the filling film embedded in the trench.

39. The method of manufacturing a semiconductor device according to claim 36, wherein the step (c) comprises a step of forming a third semiconductor region of the first conductive type such that the third semiconductor region reaches the inside of the semiconductor substrate from the surface of the first semiconductor region, and
wherein a concentration of impurities in the third semiconductor region is higher than that in the semiconductor substrate.

40. A method of manufacturing a semiconductor device, comprising the steps of:
(a) preparing a semiconductor substrate of a first conductive type;
(b) selectively forming a first semiconductor region of a second conductive type opposite to the first conductive type in a first active region of the semiconductor substrate and not in a second active region of the semiconductor substrate;
(c) forming a pair of first trenches reaching an inside of the semiconductor substrate from a surface of the first semiconductor region to isolate the first active region, and forming a pair of second trenches reaching the inside of the semiconductor substrate from the surface thereof to isolate the second active region;
(d) forming a protective insulating film over the first semiconductor region and over inner walls of the pair of the first trenches and inner walls of the pair of the second trenches;
(e) forming a first opening in the protective insulating film formed in the first active region, and forming a second opening in the protective insulating film formed in the second active region by processing the protective insulating film;
(f) forming an under bump metal film over the first semiconductor region exposed from the first opening, over the semiconductor substrate exposed from the second opening, and over the protective insulating film;
(g) forming a first bump electrode over the under bump metal film formed in the first active region, and forming a second bump electrode over the under bump metal film formed in the second active region; and
(h) separating the under bump metal film formed in the first active region from the under bump metal film formed in the second active region to thereby form a first under bump metal film in the first active region and a second under bump metal film in the second active region,
wherein in the step (h), the first under bump metal film is processed so as to extend from an inside of the first opening and to cover inner walls of the pair of the first trenches, and the second under bump metal film is processed to extend from an inside of the second opening and to cover inner walls of the pair of the second trenches.
